(19) United States
(12) Patent Application Publication
(10) Pub. No.: US 2007/0290223 A1
(43) Pub. Date: Dec. 20, 2007

(54) Semiconductor memory device and method of manufacturing the same

(76) Inventor: Atsushi Yagishita, Somers, NY (US)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/802,852

(22) Filed: May 25, 2007

(30) Foreign Application Priority Data
May 26, 2006 (JP) 2006-146479

(51) Int. Cl. H01L 33/00

(52) U.S. Cl. 257/103

(57) ABSTRACT

A semiconductor memory device includes an insulating film formed on a semiconductor substrate, a fin-shaped semiconductor layer formed on the insulating film, and having first and second side surfaces opposing each other, a gate electrode formed across the first side surface and second side surface of the semiconductor layer, a trap layer formed between the gate electrode and the first side surface of the semiconductor layer, a tunnel gate insulating film formed between the trap layer and the first and second side surfaces of the semiconductor layer, a block layer formed between the trap layer and the gate electrode, a channel region formed in the semiconductor layer below the gate electrode, and a source and drain regions formed in the semiconductor layer to sandwich the channel region and containing a metal, a Schottky junction being formed between the channel region and each of the source and drain regions.

### CROSS-REFERENCE TO RELATED APPLICATIONS

This application is based upon and claims the benefit of priority from prior Japanese Patent Application No. 2006-146479, filed May 26, 2006, the entire contents of which are incorporated herein by reference.

### BACKGROUND OF THE INVENTION

1. Field of the Invention

The present invention relates to a multi-storage semiconductor memory device in which one transistor stores two bits, and a method of manufacturing the same.

2. Description of the Related Art

Recently, multi-storage EEPROM cell structures have been proposed. Non-patent references 1 to 3 are examples of the structures. Demands have arisen for micropatterning of these multi-storage memory cell structures.

[Non-patent reference 1] M. Specht et al., “Novel Dual Bit Tri-Gate Charge Trapping Memory Devices”, IEEE Electron Device Letters, VOL. 25, NO. 12, pp. 810-812, 2004

[Non-patent reference 2] J. Willer et al., “110 nm NROM technology for code and data flash products”, Digest of Technical Papers 2004 Symposium on VLSI Technology, pp. 76-77

[Non-patent reference 3] Boaz Eitan et al., “Multilevel Flash cells and their Trade-offs”, International Electron Device Meeting Technical Digest, pp. 169-172, 1996

### BRIEF SUMMARY OF THE INVENTION

A semiconductor memory device according to the first aspect of the present invention comprising a semiconductor substrate, an insulating film formed on the semiconductor substrate, a fin-shaped semiconductor layer formed on the insulating film, and having a first side surface and second side surface opposing each other, a gate electrode formed across the first side surface and second side surface of the semiconductor layer, a trap layer formed between the gate electrode and the first side surface of the semiconductor layer, a tunnel gate insulating film formed between the trap layer and the first and second side surfaces of the semiconductor layer, a block layer formed between the trap layer and the gate electrode, a channel region formed in the semiconductor layer below the gate electrode, and a source region and drain region formed in the semiconductor layer to sandwich the channel region and containing a metal, a Schottky junction being formed between the channel region and each of the source region and the drain region.

A semiconductor memory device according to the second aspect of the present invention comprising a semiconductor layer, a channel region formed in the semiconductor layer, a source region and drain region formed in the semiconductor layer to sandwich the channel region, a gate electrode opposing the channel region, a first trap layer formed between the gate electrode and the source region, a first tunnel gate insulating film formed between the first trap layer and the source region, a first block layer formed between the first trap layer and the gate electrode, a second trap layer formed between the gate electrode and the drain region, a second tunnel gate insulating film formed between the second trap layer and the drain region, a second block layer formed between the second trap layer and the gate electrode, and a first insulating film formed between the first trap layer and the second trap layer, and made of a material having a conduction band bottom level higher than a conduction band bottom level of the first trap layer and the second trap layer.

A semiconductor memory device manufacturing method according to the third aspect of the present invention comprising forming a first insulating film on a semiconductor layer, forming a gate electrode material on the first insulating film, removing the first insulating film to position side surfaces of the first insulating film inside side surfaces of the gate electrode material to form a first cavity and a second cavity on two sides of the first insulating film, forming a first tunnel gate insulating film and a first block layer on opposing surfaces of the semiconductor layer and the gate electrode material, respectively, in the first cavity, and a second tunnel gate insulating film and a second block layer on opposing surfaces of the semiconductor layer and the gate electrode material, respectively, in the second cavity, and forming a first trap layer between the first tunnel gate insulating film and the first block layer, and a second trap layer between the second tunnel gate insulating film and the second block layer, wherein a material of the first insulating film has a conduction band bottom level higher than a conduction band bottom level of a material of the first trap layer and the second trap layer.

A semiconductor memory device manufacturing method according to the fourth aspect of the present invention comprising forming a tunnel gate insulating film on a semiconductor layer, forming an interlayer dielectric film having a trench on the tunnel gate insulating film, forming a trap layer in the trench, forming a sidewall layer on side surfaces of the trench on the trap layer, removing the trap layer from a bottom of the trench exposed from the sidewall layer to expose a portion of the tunnel gate insulating film, removing the sidewall layer and the exposed portion of the tunnel gate insulating film to expose a portion of the semiconductor layer, forming, on the exposed portion of the semiconductor layer, an insulating film made of a material having a conduction band bottom level higher than a conduction band bottom level of a material of the trap layer, forming a block layer on the trap layer and the insulating film, and forming a gate electrode in the trench on the block layer.

### BRIEF DESCRIPTION OF THE SEVERAL VIEWS OF THE DRAWING

FIG. 1 is perspective view showing a semiconductor memory device according to Embodiment 1-1 of the present invention;

FIGS. 2A and 2B are sectional views of the semiconductor memory device taken along a line II-II in FIG. 1;

FIG. 3A is a plan view of the semiconductor memory device taken along a line III-III in FIG. 1;

FIG. 3B is a sectional view of the semiconductor memory device taken along the line III-III in FIG. 1;

FIGS. 4 to 11 are perspective views showing manufacturing steps of the semiconductor memory device according to Embodiment 1-1 of the present invention;

FIGS. 12(a) to 12(d) are schematic views showing potential shapes when hot carriers are generated at the drain end in a semiconductor memory device according to prior art;

FIG. 13 is a view showing biasing conditions for performing data write, read, and erase in the semiconductor memory device according to the prior art;

FIGS. 14(a) to 14(c) are schematic views showing potential shapes when hot carriers are generated at the source end in the semiconductor memory device according to Embodiment 1-1 of the present invention;

FIG. 15 is a view showing biasing conditions for performing data write, read, and erase in the semiconductor memory device according to Embodiment 1-1 of the present invention;

FIG. 16A is a plan view showing a semiconductor memory device according to Embodiment 1-2 of the present invention;

FIG. 16B is a sectional view showing the semiconductor memory device according to Embodiment 1-2 of the present invention;

FIG. 17A is a plan view showing a semiconductor memory device according to Embodiment 1-3 of the present invention;

FIG. 17B is a sectional view showing the semiconductor memory device according to Embodiment 1-3 of the present invention;

FIGS. 18 to 20 are perspective views showing manufacturing steps of the semiconductor memory device according to Embodiment 1-3 of the present invention;

FIG. 21 is a circuit diagram showing memory cells of a semiconductor memory device according to Embodiment 1-4 of the present invention;

FIG. 22 is a planar layout pattern diagram showing the memory cells of the semiconductor memory device according to Embodiment 1-4 of the present invention;

FIG. 23 is a sectional view showing a semiconductor memory device according to Embodiment 2-1 of the present invention;

FIGS. 24 to 29 are sectional views showing manufacturing steps of the semiconductor memory device according to Embodiment 2-1 of the present invention;

FIG. 30 is a view for explaining a problem related to Embodiment 2-1 of the present invention;

FIG. 31 is a perspective view showing a semiconductor memory device according to Embodiment 2-2 of the present invention;

FIG. 32 is a plan view showing the semiconductor memory device according to Embodiment 2-2 of the present invention;

FIGS. 33 to 41 are perspective views showing manufacturing steps of the semiconductor memory device according to Embodiment 2-2 of the present invention;

FIGS. 42 to 45 are plan views showing manufacturing steps of the semiconductor memory device according to Embodiment 2-2 of the present invention;

FIG. 46 is a sectional view showing a semiconductor memory device according to Embodiment 2-3 of the present invention;

FIG. 47 is a plan view showing a semiconductor memory device according to Embodiment 2-4 of the present invention;

FIGS. 48 to 59 are sectional views showing manufacturing steps of a semiconductor memory device according to Embodiment 2-5 of the present invention;

FIGS. 60 to 64 are perspective views showing manufacturing steps of a semiconductor memory device according to Embodiment 2-6 of the present invention;

FIG. 65 is a plan view showing a manufacturing step of a semiconductor memory device according to Embodiment 2-6 of the present invention;

FIG. 66 is a perspective view showing a semiconductor memory device according to Embodiment 3-1 of the present invention;

FIG. 67 is a plan view showing the semiconductor memory device according to Embodiment 3-1 of the present invention;

FIGS. 68 to 71 are perspective views showing manufacturing steps of the semiconductor memory device according to Embodiment 3-1 of the present invention;

FIG. 72 is a perspective view showing a semiconductor memory device according to Embodiment 3-2 of the present invention;

FIG. 73 is a plan view showing the semiconductor memory device according to Embodiment 3-2 of the present invention;

FIGS. 74 to 77 are perspective views showing manufacturing steps of the semiconductor memory device according to Embodiment 3-2 of the present invention;

FIG. 78 is a circuit diagram showing memory cells of a semiconductor memory device according to Embodiment 3-3 of the present invention;

FIG. 79 is a planar layout pattern diagram showing the memory cells to the level of a word line layer of the semiconductor memory device according to Embodiment 3-3 of the present invention;

FIG. 80 is a planar layout pattern diagram showing the memory cells to the level of a source line layer of the semiconductor memory device according to Embodiment 3-3 of the present invention;

FIG. 81 is a planar layout pattern diagram showing the memory cells to the level of a bit line layer of the semiconductor memory device according to Embodiment 3-3 of the present invention; and

FIG. 82 is a sectional view showing the memory cells of the semiconductor memory device taken along a line LXXXII-LXXXII in FIG. 81.

### DETAILED DESCRIPTION OF THE INVENTION

Embodiments of the present invention will explain three examples of a multi-storage EEPROM in which one transistor stores two bits. The basis of the first and second examples is a metal-oxide-nitride-oxide-semiconductor (MONOS) nonvolatile memory. The basis of the third example is a floating nonvolatile memory. The first to third examples according to the embodiments of the present invention will be explained below with reference to the accompanying drawing.

### [1] First Example

Each semiconductor memory device according to the first example of the present invention is obtained by applying a Schottky metal oxide semiconductor field-effect transistor (MOSFET) to a multi-storage EEPROM. The Schottky MOSFET is a MOSFET in which a source and drain have metal-silicon junctions (Schottky junctions) rather than p-n junctions.

### [1-1] Embodiment 1-1

Embodiment 1-1 is a Fin-type Schottky MOSFET that uses an oxide-nitride-oxide (ONO) film to store data by storing electric charge in the trap of the nitride film sandwiched between the oxide films.

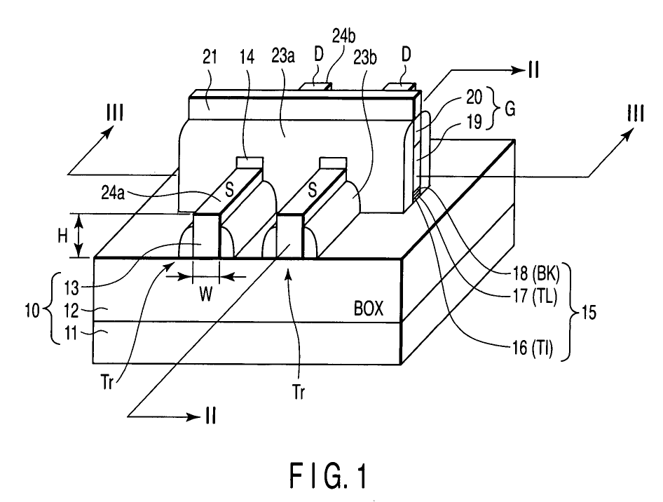

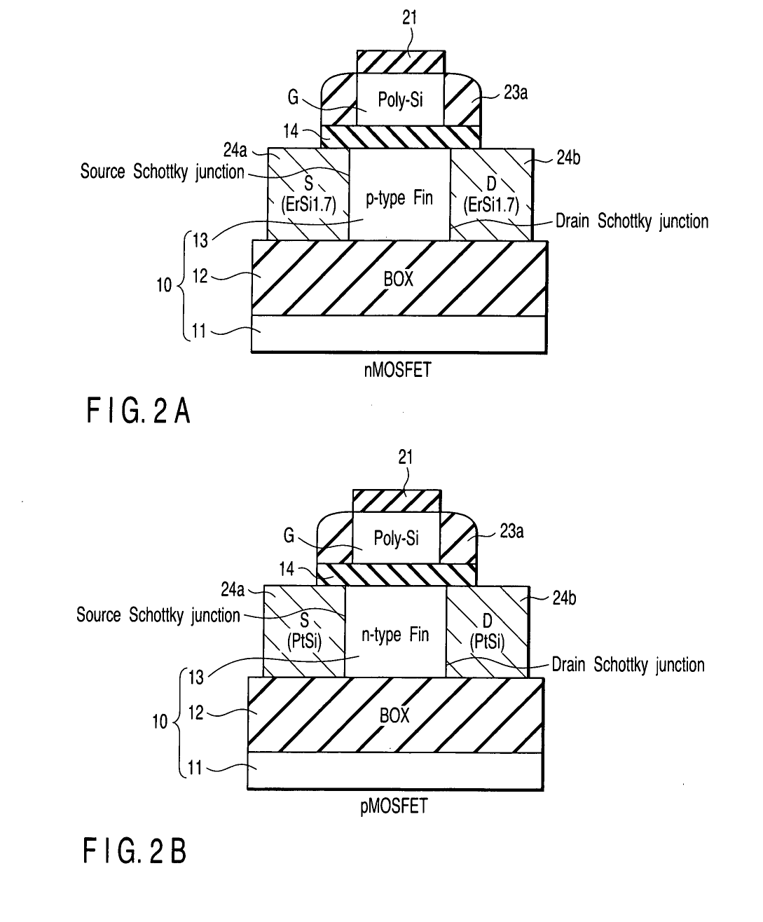

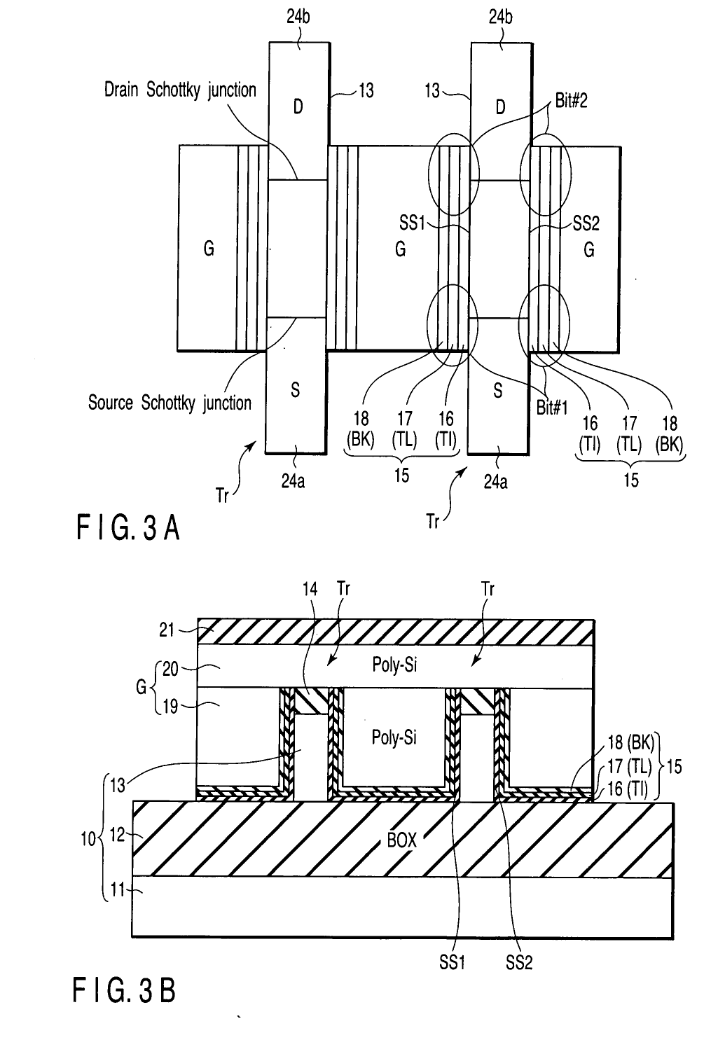

FIG. 1 is a perspective view of the semiconductor memory device according to Embodiment 1-1 of the present invention. FIGS. 2A and 2B are sectional views of the semiconductor memory device taken along a line II-II in FIG. 1. FIGS. 3A and 3B are a plan view and sectional view, respectively, of the semiconductor memory device taken along a line III-III in FIG. 1. The semiconductor memory device according to Embodiment 1-1 of the present invention will be explained below.

As shown in FIGS. 1, 2A, 2B, 3A, and 3B, this embodiment uses a silicon-on-insulator (SOI) substrate 10. The SOI substrate 10 has a semiconductor substrate (e.g., an Si substrate) 11, a buried insulating film (buried oxide [BOX]) 12 formed on the semiconductor substrate 11, and SOI layers (semiconductor layers) 13 formed on the buried insulating film 12.

Each SOI layer 13 has a fin shape. That is, the SOI layer 13 has side surfaces SS1 and SS2 opposing each other. A gate electrode G is formed across the side surfaces SS1 and SS2 of the SOI layer 13.

ONO films 15 are formed between the gate electrode G and the side surfaces SS1 and SS2 of the SOI layer 13. More specifically, as shown in FIGS. 3A and 3B, SiN films 17 (trap layers TL) are formed between the gate electrode G and the side surface SS1 of the SOI layer 13 and between the gate electrode G and the side surface SS2 of the SOI layer 13. Oxide films 16 (tunnel gate insulating films TI) are formed between the SiN film 17 and the side surface SS1 of the SOI layer 13 and between the SiN film 17 and the side surface SS2 of the SOI layer 13. Oxide films 18 (block layers BK, control gate insulating films CI) are formed between the SiN films 17 and gate electrode G.

The SOI layer 13 below the gate electrode G is a channel region, and a hard mask 14 exists between the gate electrode G and channel region. Metal source/drain regions 24a and 24b containing a metal are formed in the SOI layer 13 so as to sandwich the channel region. This forms Schottky junctions formed between the channel region and the metal source/drain regions 24a and 24b.

As the silicide material of the metal source/drain regions 24a and 24b, it is possible to use, e.g., ErSi for an n-channel MOS transistor (FIG. 2A), and PtSi for a p-channel MOS transistor (FIG. 2B). Other examples of the silicide material for an n-channel MOS transistor are arsenic (As)-doped or phosphorus (P)-doped NiSi, CoSi₂, YbSi₂, YSi₂, YSi, GdSi₂, DySi₂, HoSi₂, LaSi₂, and LaSi. Other examples of the silicide material for a p-channel MOS transistor are boron (B)-doped NiSi, CoSi₂, Pd₂Si, PdSi, IrSi, IrSi₂, and IrSi₃.

In the semiconductor memory device as described above, one transistor Tr stores two bits. That is, the trap layer TL on the side of the metal source region 24a functions as a 1-bit write region Bit#1, and the trap layer TL on the side of the metal drain region 24b functions as a 1-bit write region Bit#2. Thus, one transistor Tr secures write regions for a total of two bits.

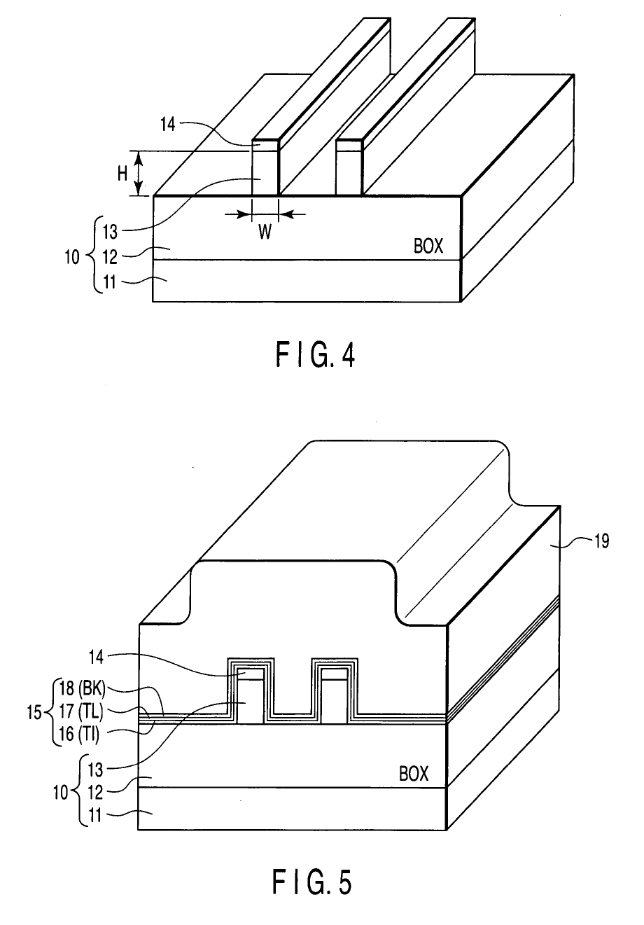

FIGS. 4 to 11 are perspective views showing manufacturing steps of the semiconductor memory device according to Embodiment 1-1 of the present invention. A method of manufacturing the semiconductor memory device according to Embodiment 1-1 of the present invention will be explained below.

First, as shown in FIG. 4, an SOI substrate 10 having a semiconductor substrate (e.g., an Si substrate) 11, buried insulating film (BOX) 12, and SOI layer 13 is prepared. Doping is then performed on a body region as a prospective channel region of the SOI layer 13. A hard mask 14 is deposited on the SOI layer 13, and patterned into a fin shape. The hard mask 14 is made of, e.g., an SiN film about 70 nm thick. The hard mask 14 is used to process the SOI layer 13 into a fin shape by anisotropic etching such as reactive ion etching (RIE). Each fin-shaped SOI layer 13 has a height H of, e.g., about 50 to 100 nm, and a width W of, e.g., about 10 nm.

Then, as shown in FIG. 5, an ONO film 15 is deposited on the hard masks 14 and buried insulating film 12, and formed on the side surfaces of the fin-shaped SOI layers 13. The ONO film 15 is formed, e.g., as follows. First, a 3-nm-thick oxide film 16 is formed in an N₂/O₂ ambient by a rapid-thermal-process. On the oxide film 16, an SiN film (e.g., an Si₃N₄ film) 17 about 5 nm thick is deposited by chemical vapor deposition (CVD). An oxide film (SiO₂ film) 18 about 5 nm thick is formed on the SiN film 17. After the ONO film 15 is thus formed, a first polysilicon layer 19 about 300 nm thick is deposited on the ONO film 15. Since the first polysilicon layer 19 is deposited on the fin-shaped SOI layers 13, a large step is formed on the surface of the first polysilicon layer 19.

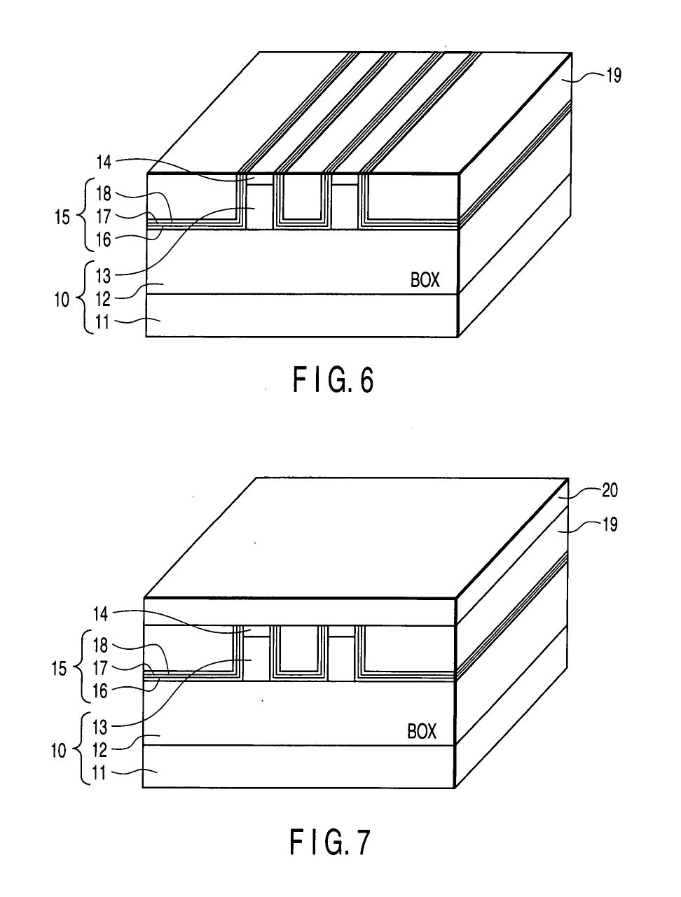

As shown in FIG. 6, after the first polysilicon layer 19 is planarized by, e.g., chemical mechanical polishing (CMP), the first polysilicon layer 19 and ONO film 15 are etched back until the hard masks 14 are exposed.

Subsequently, as shown in FIG. 7, a second polysilicon layer 20 about 50 nm thick is deposited on the first polysilicon layer 19 and hard masks 14. Note that the first and second polysilicon layers 19 and 20 are used as the materials of a gate electrode G.

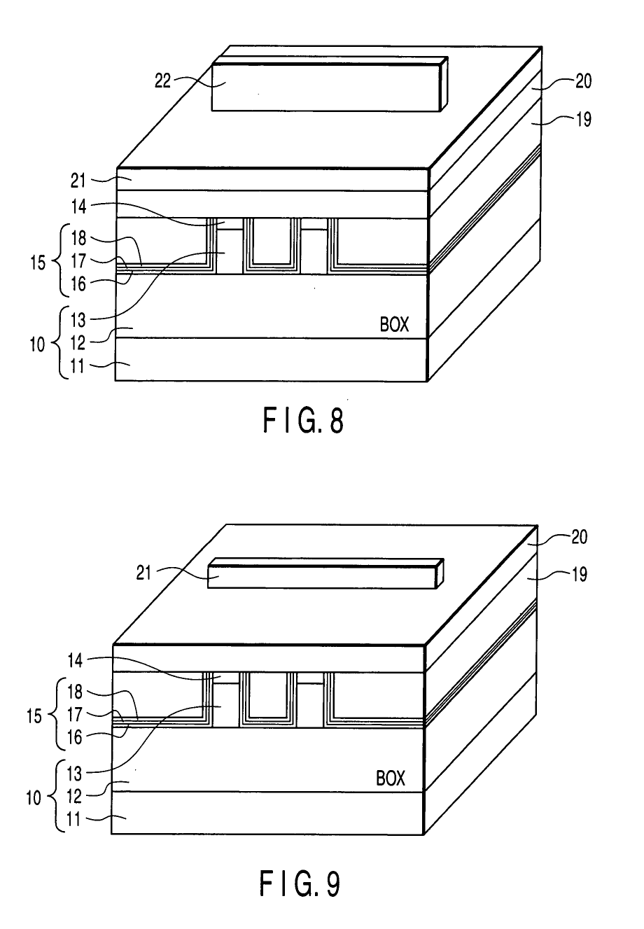

As shown in FIG. 8, a hard mask 21 about 100 nm thick made of an SiN film is deposited on the second polysilicon layer 20, and a resist 22 is formed on the hard mask 21. The resist 22 is then processed into a gate pattern by lithography.

As shown in FIG. 9, the resist 22 is used to process the hard mask 21 into the gate pattern by RIE. After that, the resist 22 is removed.

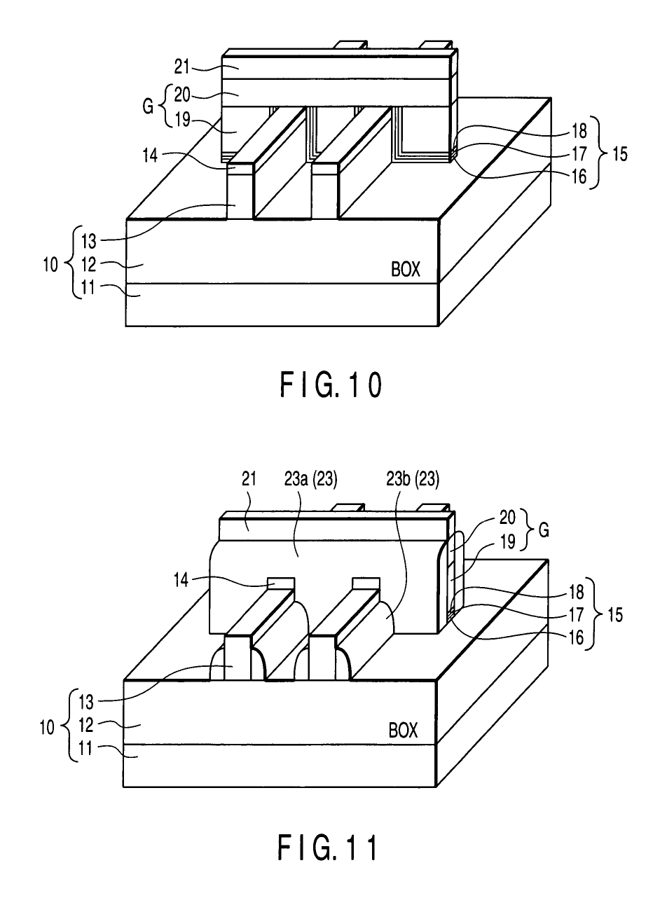

As shown in FIG. 10, the hard mask 21 is used to process the first and second polysilicon layers 19 and 20 and the ONO film 15 by RIE. As a consequence, a gate electrode G is formed across the SOI layers 13.

As shown in FIG. 11, a sidewall material 23 made of, e.g., SiO₂ using tetra ethyl ortho silicate (TEOS) is deposited on the hard masks 14 and 21 and the buried insulating film 12, and etched back. This forms gate sidewall layers 23a about 40 nm thick on the side surfaces of the gate electrode G, and fin sidewall layers 23b about 40 nm thick on the side surfaces of the SOI layers 13. After that, the hard masks 14 made of an SiN film on the SOI layers 13 are etched away by SiN-RIE. Note that the hard mask 21 made of an SiN film is left behind on the gate electrode G by adjusting the etching conditions.

Then, as shown in FIGS. 1, 2A, 2B, 3A, and 3B, the SOI layers 13 in prospective source/drain regions are silicidized to form metal source/drain regions 24a and 24b. Note that the gate electrode G is not silicidized because it is covered with the hard mask 21 and gate sidewall layers 23a. Manufacturing steps after that are similar to the conventional LSI manufacturing steps. That is, an interlayer film is deposited, contact holes are formed, and an upper interconnection layer is formed.

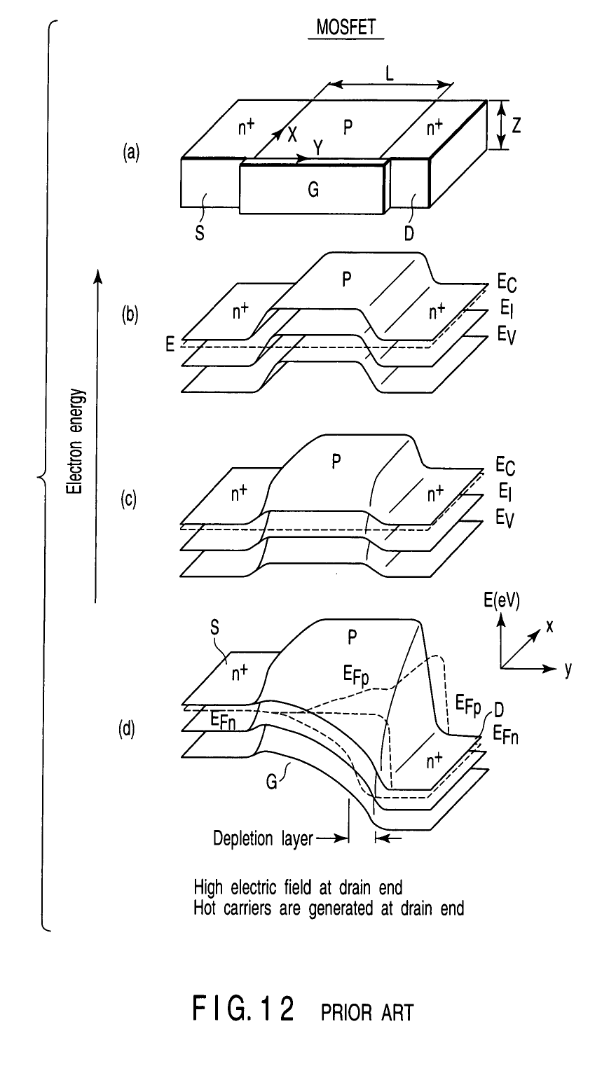

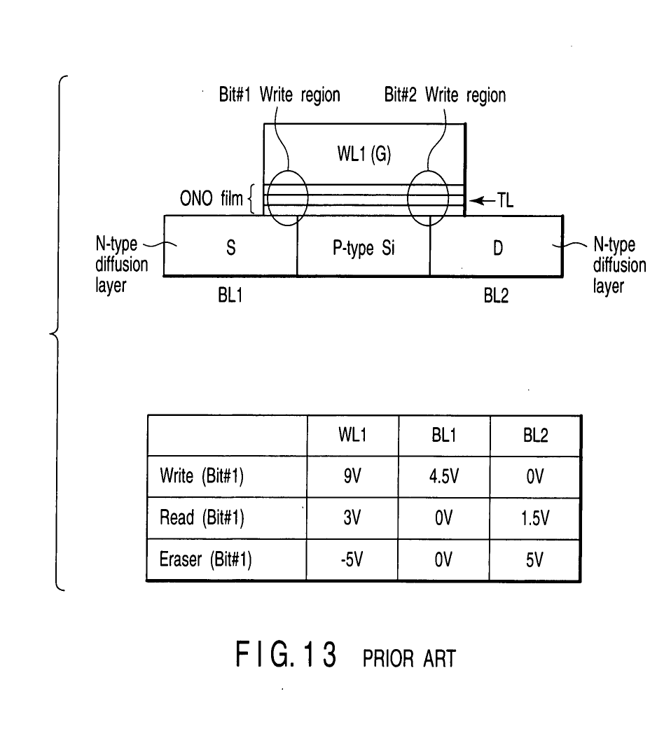

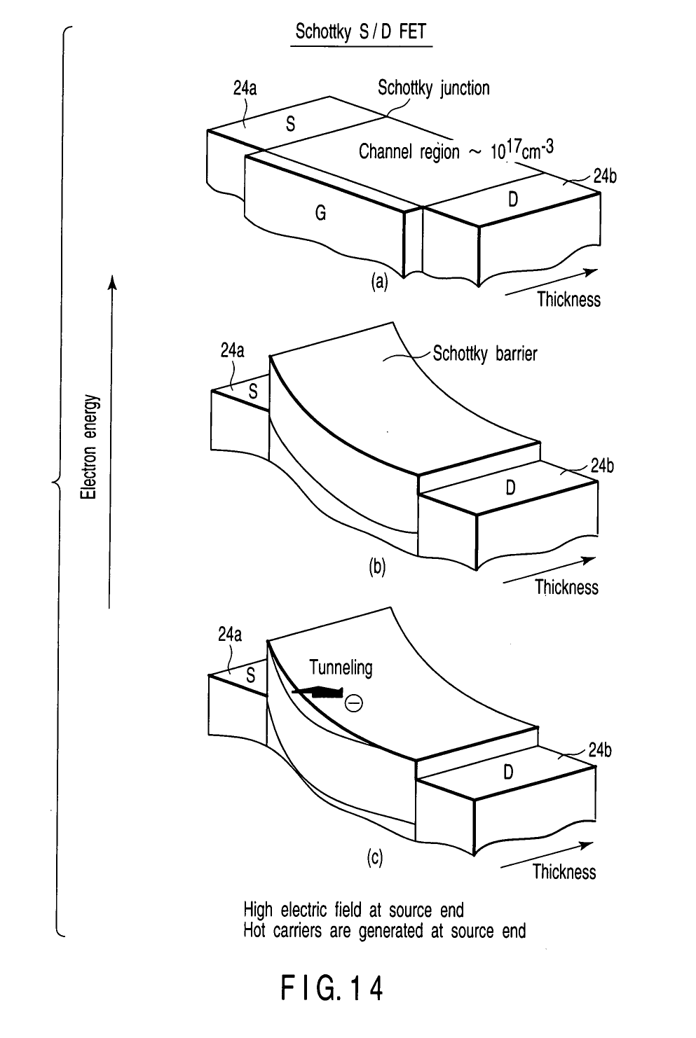

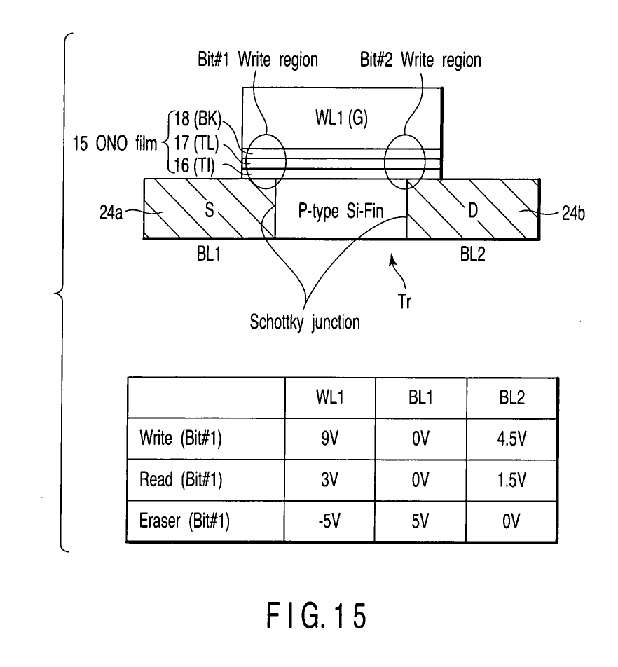

FIGS. 12(a) to 12(d) are schematic views showing potential shapes when hot carriers are generated at the drain end in a semiconductor memory device according to prior art. FIG. 13 shows biasing conditions for performing data write, read, and erase in the semiconductor memory device according to the prior art. FIGS. 14(a) to 14(c) are schematic views showing potential shapes when hot carriers are generated at the source end in the semiconductor memory device according to Embodiment 1-1. FIG. 15 shows biasing conditions for performing data write, read, and erase in the semiconductor memory device according to Embodiment 1-1.

The conventional MOSFET has source/drain diffusion layers formed by p-n junctions. In this conventional device structure, as shown in FIGS. 12(a) to 12(d), hot carriers (electrons) generated at the drain end by a high electric field are injected into a trap layer TL (a nitride film when an ONO film is used) near the drain, thereby writing data (in, e.g., a region Bit#2 shown in FIG. 13). On the other hand, data read requires a “reverse read” operation that switches the source-to-drain voltages from those of data write, in order to increase the trap charge detection sensitivity. That is, as shown in FIG. 13, 1.5 V of BL1 and 0 V of BL2 in data write are switched to 0 V of BL1 and 4.5 V of BL2 in data read. Accordingly, the source-to-drain biases, i.e., the electron flow directions in data write and data read must be switched, and this complicates the circuit control. It is also difficult for the conventional device structure to achieve a low resistance and shallow junctions of the source/drain diffusion layers. This makes it difficult to increase the degree of micropatterning and raise the density of the EEPROM.

By contrast, the semiconductor memory device of Embodiment 1-1 of the present invention is a MOSFET having the metal source/drain regions 24a and 24b formed by Schottky junctions. In this device structure of Embodiment 1-1 of the present invention, as shown in FIGS. 14(a) to 14(c), a high electric field is generated at the source end, and hot carriers (electrons) generated at this source end are injected into the trap layer TL near the source, thereby writing data (in, e.g., a region Bit#1 shown in FIG. 15). On the other hand, because the trap charge exists near the source in data read, data in, e.g., the region Bit#1 can be read out at high sensitivity by biasing conditions in the same direction as in data write without changing the electron flow direction. Accordingly, the biasing conditions for performing data write, read, and erase in the device of Embodiment 1-1 are as shown in FIG. 15, unlike in the conventional device. That is, BL1 and BL2 can be 0 and 4.5 V, respectively, in data write and 0 and 1.5 V, respectively, in data read. This makes it possible to use biasing conditions in the same direction in the write and read operations.

As described above, the multi-storage EEPROM of Embodiment 1-1 of the present invention is a Schottky MOSFET having the metal source/drain regions 24a and 24b. Therefore, it is possible to decrease the resistance and shallow the junctions of the source and drain. This makes it possible to increase the degree of micropatterning, raise the density, and reduce the cost of a multi-storage EEPROM using a Fin-FET.

Also, the use of the metal source/drain regions 24a and 24b formed by Schottky junctions generates a high electric field at the source end, and injects hot carriers (electrons) into the trap layer TL (SiN film 17) near the source. This makes the source/drain biasing direction (positive or negative) during data write the same as that during data read (makes the electron flow directions in data write and data read the same). That is, the source/drain biases (electron flow directions) in data write and data read need not be switched. This obviates the need for reverse read, unlike in the conventional device. Accordingly, it is possible to simplify the operations of the data write and read circuits, thereby making these circuits easy to control.

Furthermore, an LSI can be readily manufactured because the Schottky source and drain require no high-temperature annealing step (to about 1,000° C.).

### [1-2] Embodiment 1-2

Embodiment 1-2 is a Fin-type Schottky MOSFET in which a trap layer TL for storing electric charge is a high-k film. The high-k film is a film having a relative dielectric constant larger than the dielectric constant (7.5) of SiN.

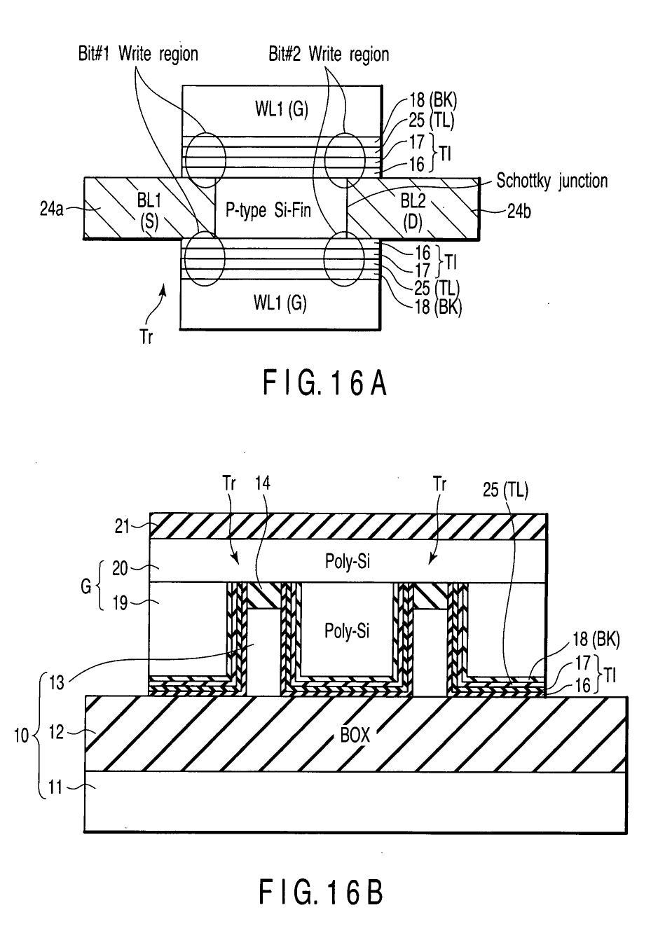

FIG. 16A is a plan view of a semiconductor memory device according to Embodiment 1-2 of the present invention. FIG. 16B is a sectional view of the semiconductor memory device according to Embodiment 1-2 of the present invention. The semiconductor memory device according to Embodiment 1-2 of the present invention will be explained below.

As shown in FIGS. 16A and 16B, Embodiment 1-2 differs from Embodiment 1-1 in that high-k films 25 are used as trap layers TL. Examples of the high-k film 25 are an HfO₂ film, ZrO₂ film, TiO₂ film, an oxide material including Al, Y, Ta, or La, a mixture material (e.g., LaAlO) of that, a material (e.g., HfSiON) of that including N.

Note that this embodiment exhibits the structure obtained by adding the high-k films 25 to the structure of Embodiment 1-1, but it is also possible to eliminate SiN films 17.

A manufacturing method of this embodiment is almost the same as Embodiment 1-1, so a detailed explanation thereof will be omitted. The formation conditions of a stacked gate insulating film are as follows.

First, an oxynitride film about 2 nm thick is formed in an N₂/O₂ ambient at 800° C., and annealed in an N₂ ambient at 900° C. for a few tens min, thereby forming an oxide film 16. Then, a 2-nm-thick SiN film (e.g., an Si₃N₄ film) 17 is deposited by LPCVD. A high-k film 25 about 14 nm thick made of, e.g., an HfO₂ film is deposited by Low Pressure (LP) CVD, Metal Organic (MO) CVD or the like. Subsequently, an oxide film (SiO₂ film) 18′ about 7 nm thick is formed on the high-k film 25, and a gate electrode G is formed on the oxide film 18.

As described above, the multi-storage EEPROM of Embodiment 1-2 of the present invention can achieve not only the same effects as in Embodiment 1-1 but also the following effects.

Conventionally, a high-temperature annealing process is necessary to form source/drain diffusion layers, and this makes it difficult to use a low-heat-resistance (thermally unstable) high-k film as a trap layer TL.

By contrast, Embodiment 1-2 of the present invention forms the metal source/drain regions 24a and 24b without forming any source/drain diffusion layers. This eliminates the need for the high-temperature annealing process for forming source/drain diffusion layers, and makes a low-temperature formation process usable. Accordingly, the low-heat-resistance (thermally unstable) high-k film 25 can be used as the trap layer TL, so it is possible to increase the operating speed and prolong the retention time of the EEPROM.

### [1-3] Embodiment 1-3

Embodiment 1-3 is a Fin-type Schottky MOSFET in which a trap layer TL for storing electric charge is a high-k film, and the gate electrode is made of a metal material.

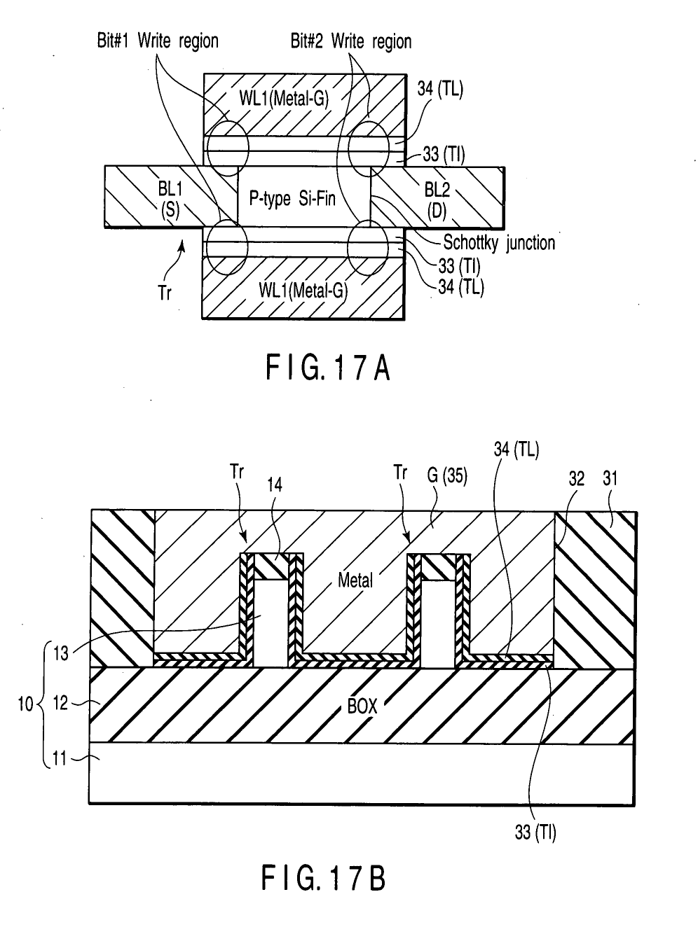

FIG. 17A is a plan view of the semiconductor memory device according to Embodiment 1-3 of the present invention. FIG. 17B is a sectional view of the semiconductor memory device according to Embodiment 1-3 of the present invention. The semiconductor memory device according to Embodiment 1-3 of the present invention will be explained below.

As shown in FIGS. 17A and 17B, Embodiment 1-3 differs from Embodiment 1-1 in that high-k films 34 are used as trap layers TL, and a metal material is used as a gate electrode G. Examples of the high-k film 34 are a TiO₂ film, ZrO₂ film, and HfO₂ film as the material using the high-k film 25. Examples of the metal material of the gate electrode G are Al, Ti, Zr, Hf, Ta, and Mo, a material (e.g., TiN, WN, TaN) of that including N, a material (e.g., HfC, TaC) of that including C, a mixture material of that. The metal material of the gate electrode G may be included Si, Ge, F, B, P, As, Sn, Ga, In, La, Sb, S, Cl, O of 10 atomic % or less to improve of the thermally stable and to control of the work function.

The gate electrode G has a so-called damascene structure. That is, as shown in FIG. 17B, the upper surface of the gate electrode G is leveled with the upper surface of an interlayer dielectric film 31 buried around the gate electrode G.

Note that in this embodiment, the block layer BK of Embodiments 1-1 and 1-2 does not exist between the trap layer TL made of the high-k film 34 and the gate electrode G. This is so because when the high-k film 34 having a deep trap level is used as the trap layer TL, a sufficient retention time can be assured without the block layer BK. In this embodiment, however, the block layer BK may also be formed between the trap layer TL and gate electrode G.

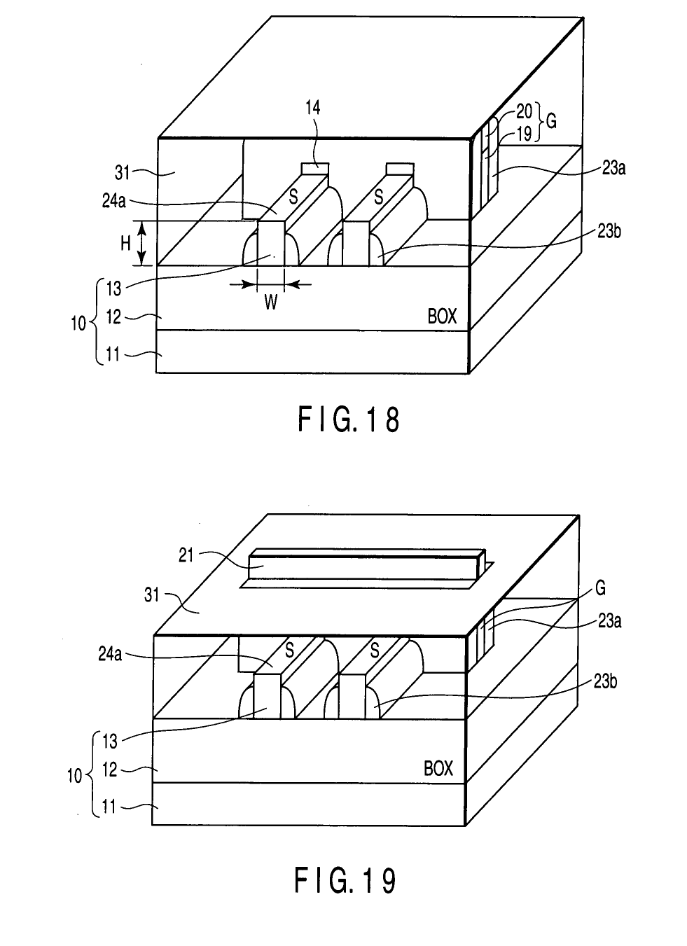

FIGS. 18 to 20 are perspective views showing manufacturing steps of the semiconductor memory device according to Embodiment 1-3 of the present invention. A method of manufacturing the semiconductor memory device according to Embodiment 1-3 of the present invention will be explained below.

First, the semiconductor memory device shown in FIG. 1 is formed through the steps shown in FIGS. 4 to 11 following the same procedures as in Embodiment 1-1. In this embodiment, however, a gate insulating film made of a thermal oxide film (SiO₂ film) is formed instead of the ONO film 15.

Then, as shown in FIG. 18, an interlayer dielectric film 31 about 400 nm thick made of SiO₂ using TEOS or the like is deposited, and planarized by CMP.

As shown in FIG. 19, the entire surface of the interlayer dielectric film 31 is etched back to expose a hard mask 21 on a gate electrode G.

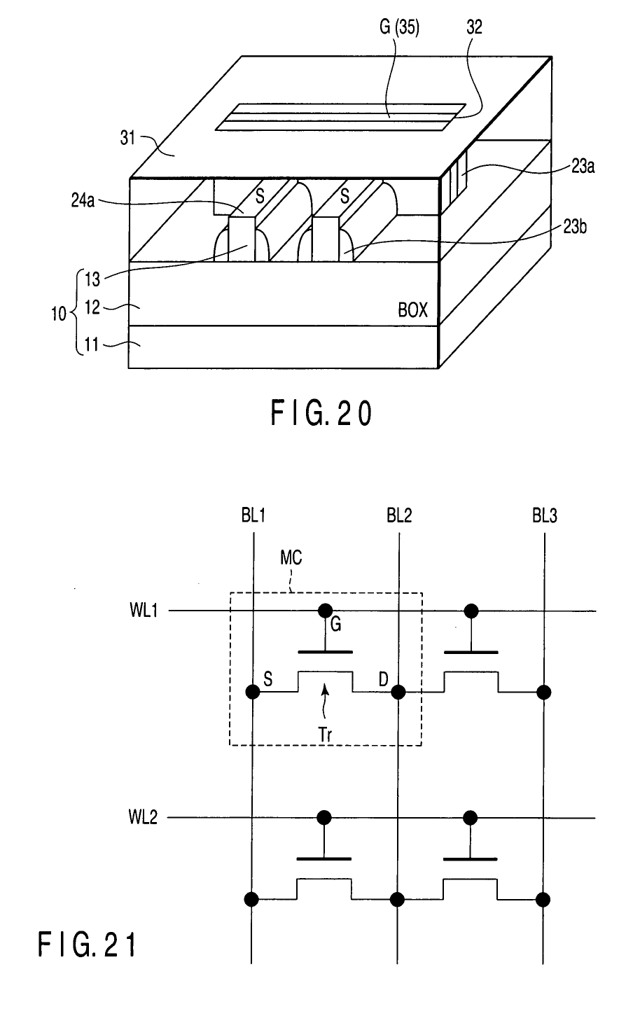

Subsequently, as shown in FIG. 20, the hard mask 21 is removed by hot phosphoric acid or the like, thereby exposing the upper surface of the gate electrode G. A gate trench 32 is formed by once removing the gate electrode G by, e.g., CDE. The gate insulating film exposed to the side surfaces of an SOI layer 13 in the gate trench 32 is removed by HF. Then, a high-k film 34 made of, e.g., a TiO₂ film is formed by sputtering at, e.g., about 400° C. This sputtering step forms an interface oxide film 33 about 1 to 2 nm thick. The removed process of the gate insulating film by HF may omit by a thermal oxide film (SiO₂) is formed beforehand. The oxide process may add before the high-k film 34 is formed. After that, a gate material 35 such as Al is deposited and planarized by the damascene process, thereby burying a gate electrode G.

As described above, the multi-storage EEPROM of Embodiment 1-3 of the present invention can achieve not only the same effects as in Embodiment 1-1 but also the following effects.

This embodiment forms the high-k film 34 serving as the trap layer TL after forming metal source/drain regions 24a and 24b, and uses a metal as the gate electrode G. This allows the trap layer TL to pass through low-temperature steps. Therefore, the low-heat-resistance (thermally unstable) high-k film 34 can be readily used as the trap layer TL.

Also, the use of the gate electrode G made of a metal makes it possible to prevent crystallization of the high-k film 34, and prevent a reaction between the high-k film 34 and gate electrode G.

### [1-4] Embodiment 1-4

Embodiment 1-4 will explain a circuit diagram and planar layout pattern diagram of memory cells according to Embodiments 1-1 to 1-3.

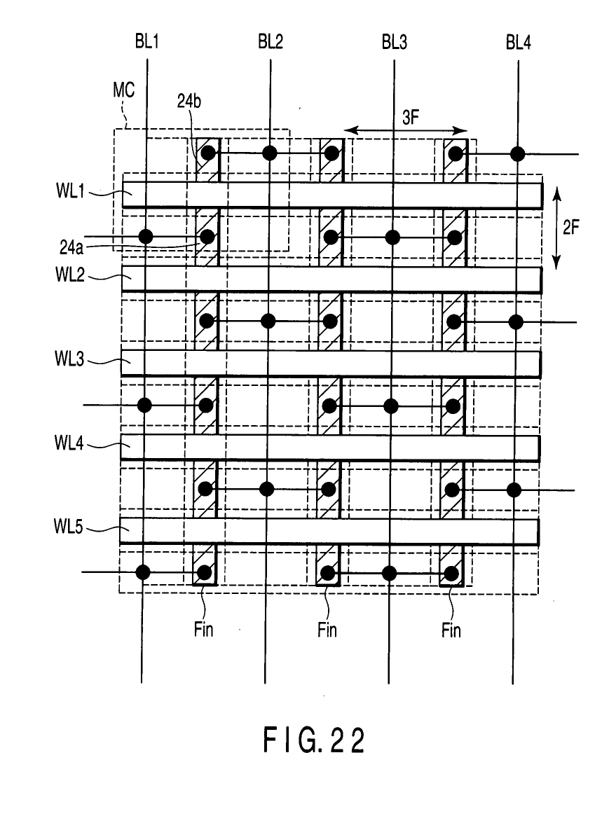

FIG. 21 is a circuit diagram of memory cells of a semiconductor memory device according to Embodiment 1-4 of the present invention. FIG. 22 is a planar layout pattern diagram of the memory cells of the semiconductor memory device according to Embodiment 1-4 of the present invention. This layout pattern is an example, and the solid lines indicate bit lines for the sake of simplicity. Note that these diagrams correspond to, e.g., the plan view of FIG. 15 in Embodiment 1-1, the plan view of FIG. 16A in Embodiment 1-2, and the plan view of FIG. 17A in Embodiment 1-3.

As shown in FIG. 21, a plurality of transistor cells as in Embodiments 1-1 to 1-3 are arranged and connected to word lines WL and bit lines BL, thereby forming a circuit. In one memory cell MC, a transistor Tr has a gate G (gate electrode G) connected to a word line WL1, a source S (metal source region 24a) connected to a bit line BL1, and a drain D (metal drain region 24b) connected to a bit line BL2.

As shown in FIG. 22, hatched portions are the metal source/drain regions 24a and 24b. Transistor cells as explained in Embodiments 1-1 to 1-3 are arranged at the intersections of the word lines WL and fins (SOI layers 13).

### [2] Second Example

Each semiconductor memory device according to the second example of the present invention is a multi-storage EEPROM having two trap layers TL, i.e., a region near the source and a region near the drain, between the gate and channel. A layer made of an insulating material (which functions as a potential barrier against trapped carriers) having a conduction band bottom level higher than that of the trap layers TL is formed between them.

### [1-1] Embodiment 2-1

Embodiment 2-1 is a planar MOSFET in which trap layers TL made of SiN films exist near the source and drain of one transistor, and an insulating layer having a conduction band bottom level higher than that of these two trap layers TL is formed between them.

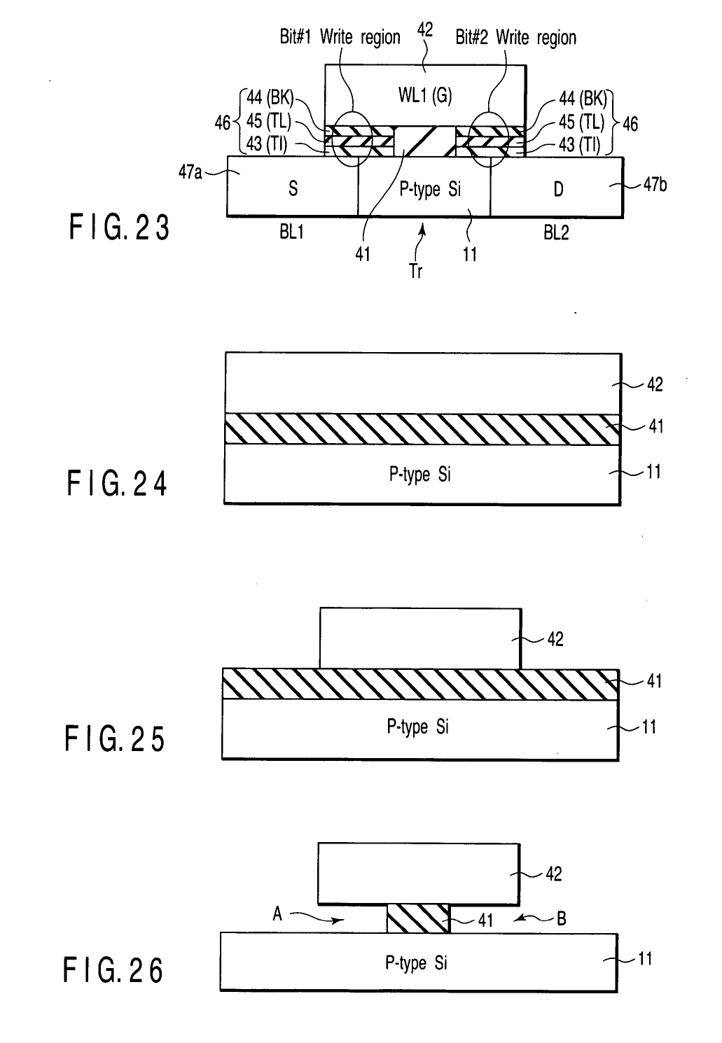

FIG. 23 is a sectional view of the semiconductor memory device according to Embodiment 2-1 of the present invention. The semiconductor memory device according to Embodiment 2-1 of the present invention will be explained below.

As shown in FIG. 23, a channel region is formed in a semiconductor substrate (e.g., an Si substrate) 11, and source/drain diffusion layers 47a and 47b are formed in the semiconductor substrate 11 so as to sandwich the channel region. A gate electrode G is formed above the channel region.

ONO films 46 are formed on the boundary between the source diffusion layer 47a and channel region and on the boundary between the drain diffusion layer 47b and channel region. More specifically, SiN films 45 (trap layers TL) are formed between the gate electrode G and source diffusion layer 47a and between the gate electrode G and drain diffusion layer 47b, respectively. Oxide films 43 (tunnel gate insulating films TI) are formed between the SiN film 45 and source diffusion layer 47a and between the SiN film 45 and drain diffusion layer 47b, respectively. Oxide films 44 (block layers BK, control gate insulating films CI) are formed between the SiN films 45 and gate electrode G.

In the semiconductor memory device as described above, one transistor Tr stores two bits. That is, the trap layer TL on the side of the source diffusion layer 47a functions as a 1-bit write region Bit#1, and the trap layer TL on the side of the drain diffusion layer 47b functions as a 1-bit write region Bit#2. Thus, one transistor Tr secures write regions for a total of two bits.

An insulating film 41 is formed between the trap layers TL in the write regions Bit#1 and Bit#2. The insulating film 41 is made of a material having a conduction band bottom level higher than that of the trap layers TL. In other words, the insulating film 41 is made of a material that functions as a potential barrier against trapped carriers. In this embodiment, the insulating film 41 is made of an SiO₂ film.

FIGS. 24 to 29 are sectional views showing manufacturing steps of the semiconductor memory device according to Embodiment 2-1 of the present invention. A method of manufacturing the semiconductor memory device according to Embodiment 2-1 of the present invention will be explained below.

First, as shown in FIG. 24, an insulating film 41 made of an SiO₂ film about 10 nm thick is formed by oxidizing a semiconductor substrate (e.g., an Si substrate) 11. A polysilicon layer 42 about 100 nm thick is deposited on the insulating film 41.

Then, as shown in FIG. 25, the polysilicon layer 42 is patterned into a gate shape by lithography and RIE.

As shown in FIG. 26, the insulating film 41 is removed by about 40 nm from the right and left by isotropic etching such as HF etching. This positions the side surfaces of the insulating film 41 inside the side surfaces of the polysilicon layer 42, forming cavities A and B on the two sides of the insulating film 41.

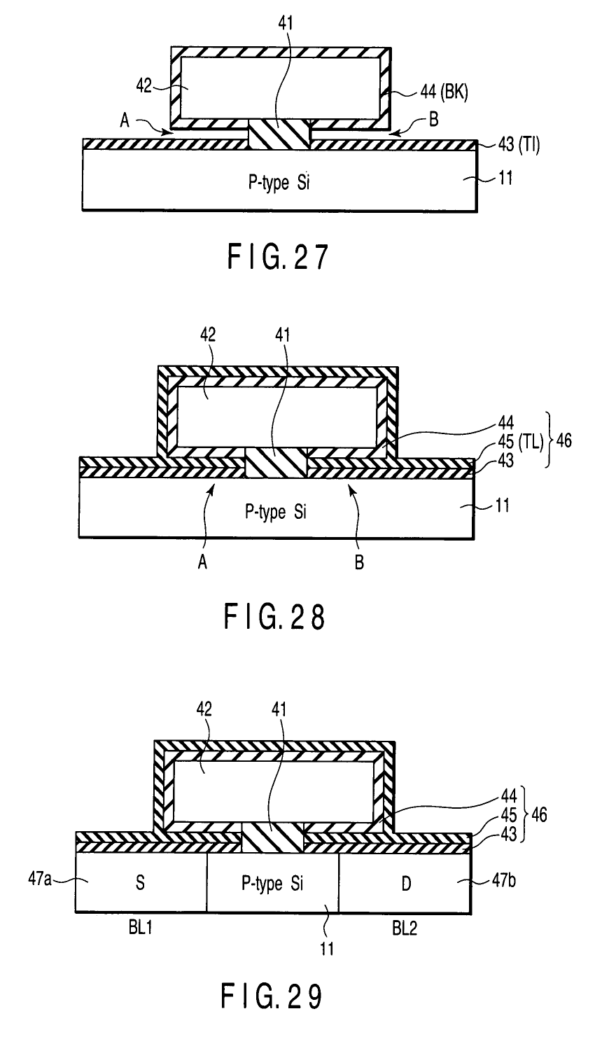

Subsequently, as shown in FIG. 27, the surfaces of the semiconductor substrate 11 and polysilicon layer 42 are simultaneously oxidized in an N₂/O₂ ambient by a rapid-thermal-process, thereby forming a 3-nm-thick oxide film (SiO₂ film) 43 and 3-nm-thick oxide film (SiO₂ film) 44. In the cavities A and B, therefore, a tunnel gate insulating film TI made of the oxide film 43 and a block layer BK made of the oxide film 44 are respectively formed on the opposing surfaces of the semiconductor substrate 11 and polysilicon layer 42.

As shown in FIG. 28, an SiN film (Si₃N₄ film) 45 about 5 nm thick is deposited as a trap layer TL by LPCVD, so as to fill the portions between the oxide films 43 and 44. In this manner, an ONO film 46 including the oxide film 43/SiN film 45/oxide film 44 is formed.

As shown in FIG. 29, source/drain diffusion layers 47a and 47b are formed in the semiconductor substrate 11 by ion implantation. Manufacturing steps after that are similar to the conventional LSI manufacturing steps. That is, an interlayer film is deposited, contact holes are formed, and an upper interconnection layer is formed.

As described above, the multi-storage EEPROM of Embodiment 2-1 of the present invention can achieve the following effects.

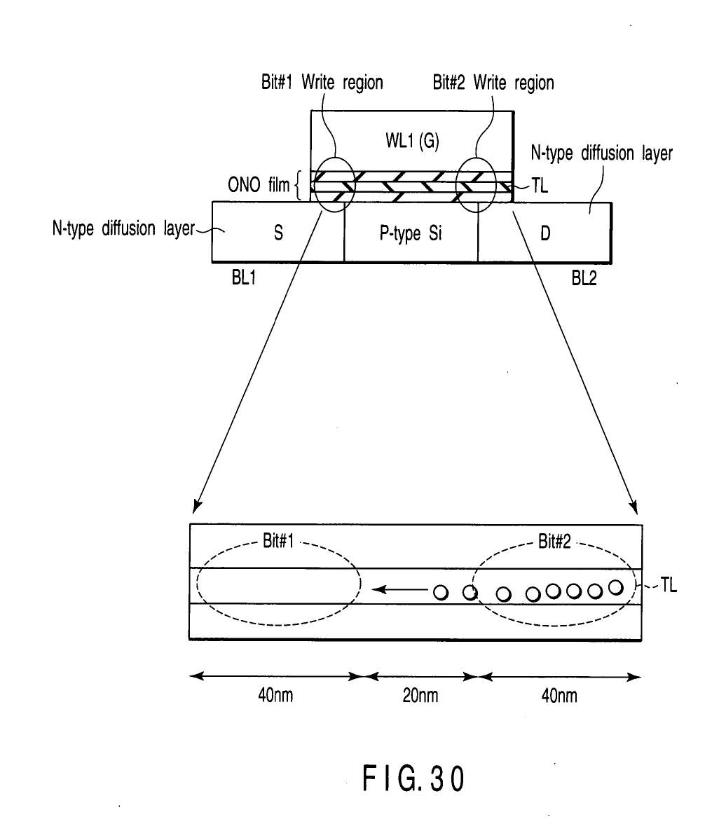

In a structure shown in FIG. 30, for example, data is written by injecting hot carriers (electrons) generated by a high electric field at the drain end into a trap layer TL near the drain. The trap layer TL continues between write regions Bit#1 and Bit#2. The width of the write regions Bit#1 and Bit#2 is about 40 nm, and the interval between them is about 20 nm. Since trapped carriers written in the write region Bit#2 diffuse in the lateral direction, therefore, these trapped carriers reach the write region Bit#1 on the opposite side if the device is micropatterned. This may change the contents of the written data and cause an operation error of the memory.

In this embodiment, however, the insulating film 41 serving as a potential barrier is formed between the trap layers TL in the write regions Bit#1 and Bit#2. This makes it difficult for carriers trapped in the trap layer TL on the source or drain side to diffuse in the lateral direction. Accordingly, the contents of the written data are held, and this improves the reliability of the device. This makes it possible to improve the performance (e.g., prevent operation errors) of the device, and increase the degrees of micropatterning and integration of the device.

### [2-2] Embodiment 2-2

Embodiment 2-2 is a double-gate Fin-MOSFET in which trap layers TL made of SiN films exist near the source and drain, respectively, of one transistor, and a layer having a conduction band bottom level higher than that of these two trap layers TL is formed between them.

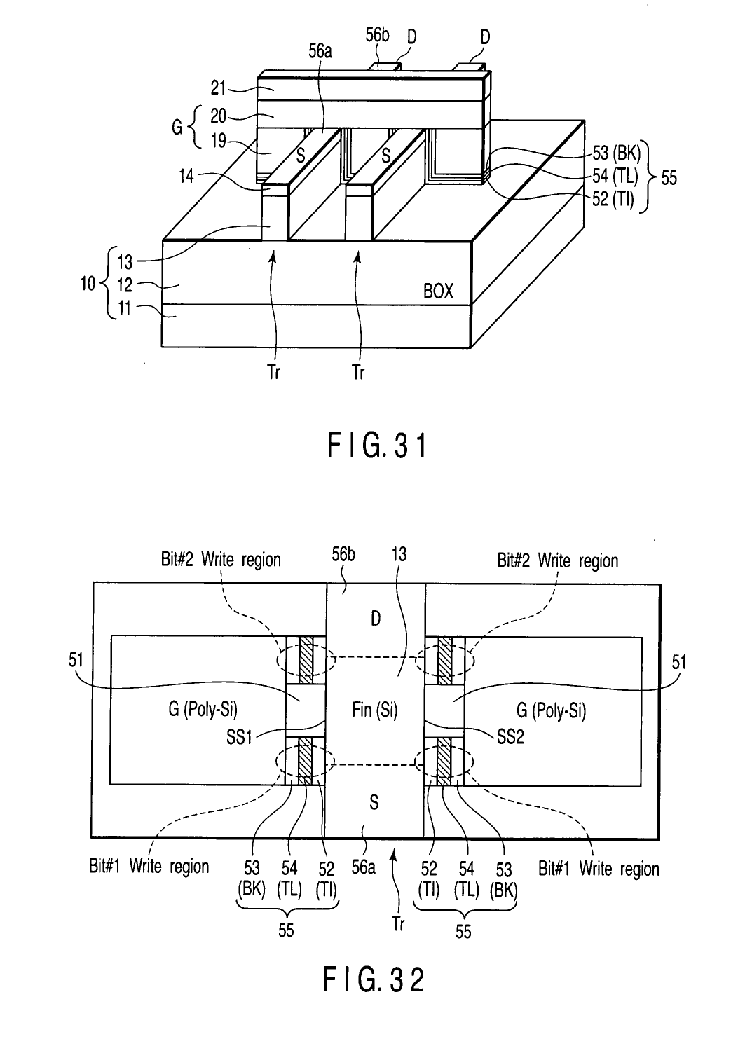

FIG. 31 is a perspective view of the semiconductor memory device according to Embodiment 2-2 of the present invention. FIG. 32 is a plan view of the semiconductor memory device according to Embodiment 2-2 of the present invention. The semiconductor memory device according to Embodiment 2-2 of the present invention will be explained below.

As shown in FIGS. 31 and 32, this embodiment uses an SOI substrate 10. The SOI substrate 10 has a semiconductor substrate (e.g., an Si substrate) 11, a buried insulating film (BOX) 12 formed on the semiconductor substrate 11, and SOI layers (semiconductor layers) 13 formed on the buried insulating film 12.

Each SOI layer 13 has a fin shape. That is, the SOI layer 13 has side surfaces SS1 and SS2 opposing each other. A gate electrode G is formed across the side surfaces SS1 and SS2 of the SOI layer 13.

ONO films 55 are formed between the gate electrode G and the side surfaces SS1 and SS2 of the SOI layer 13. More specifically, SiN films 54 (trap layers TL) are formed between the gate electrode G and the side surface SS1 of the SOI layer 13 and between the gate electrode G and the side surface SS2 of the SOI layer 13, respectively. Oxide films 52 (tunnel gate insulating films TI) are formed between the SiN film 54 and the side surface SS1 of the SOI layer 13 and between the SiN film 54 and the side surface SS2 of the SOI layer 13, respectively. Oxide films 53 (block layers BK, control gate insulating films CI) are formed between the SiN films 54 and gate electrode G.

The SOI layer 13 below the gate electrode G is a channel region, and a hard mask 14 exists between the gate electrode G and channel region. Source/drain diffusion layers 56a and 56b are formed in the SOI layer 13 so as to sandwich the channel region. Accordingly, p-n junctions are formed between the channel region and the source/drain diffusion layers 56a and 56b.

In the semiconductor memory device as described above, one transistor Tr stores two bits. That is, the trap layer TL on the side of the source diffusion layer 56a functions as a 1-bit write region Bit#1, and the trap layer TL on the side of the drain diffusion layer 56b functions as a 1-bit write region Bit#2. Thus, one transistor Tr secures write regions for a total of two bits.

An insulating film 51 is formed between the trap layers TL in the write regions Bit#1 and Bit#2. The insulating film 51 is made of a material having a conduction band bottom level higher than that of the trap layers TL. In other words, the insulating film 51 is made of a material that functions as a potential barrier against trapped carriers. In this embodiment, the insulating film 51 is made of an SiO₂ film.

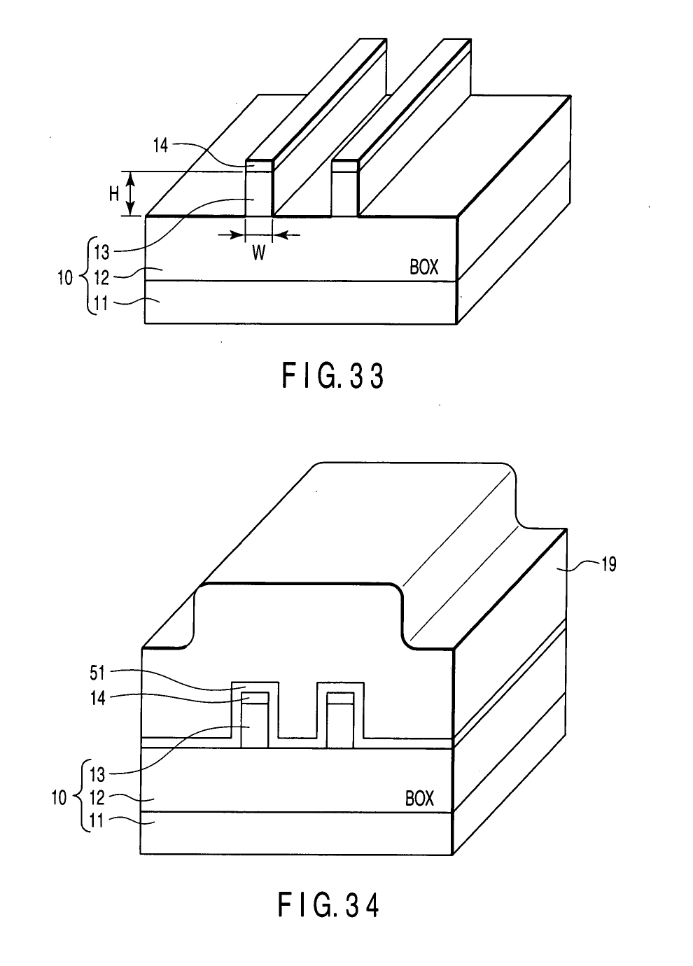

FIGS. 33 to 41 are perspective views showing manufacturing steps of the semiconductor memory device according to Embodiment 2-2 of the present invention. FIGS. 42 to 45 are plan views showing manufacturing steps of the semiconductor memory device according to Embodiment 2-2 of the present invention. A method of manufacturing the semiconductor memory device according to Embodiment 2-2 of the present invention will be explained below.

First, as shown in FIG. 33, an SOI substrate 10 having a semiconductor substrate (e.g., an Si substrate) 11, buried insulating film (BOX) 12, and SOI layer 13 is prepared. Doping is then performed on a body region as a prospective channel region of the SOI layer 13. A hard mask 14 is deposited on the SOI layer 13, and patterned into a fin shape. Each hard mask 14 is made of, e.g., an SiN film about 70 nm thick. The hard masks 14 are used to process the SOI layer 13 into a fin shape by anisotropic etching such as RIE. Each fin-shaped SOI layer 13 has a height H of, e.g., about 50 to 100 nm and a width W of, e.g., about 10 nm.

Then, as shown in FIG. 34, an insulating film 51 is deposited on the hard masks 14 and buried insulating film 12, thereby forming an insulating film 51 made of a thermal oxide film (SiO₂ film) about 10 nm thick on the side surfaces of the SOI layers 13. After that, a first polysilicon layer 19 about 300 nm thick is deposited. Since the first polysilicon layer 19 is deposited on the fin-shaped SOI layers 13, a large step is formed on the surface of the first polysilicon layer 19.

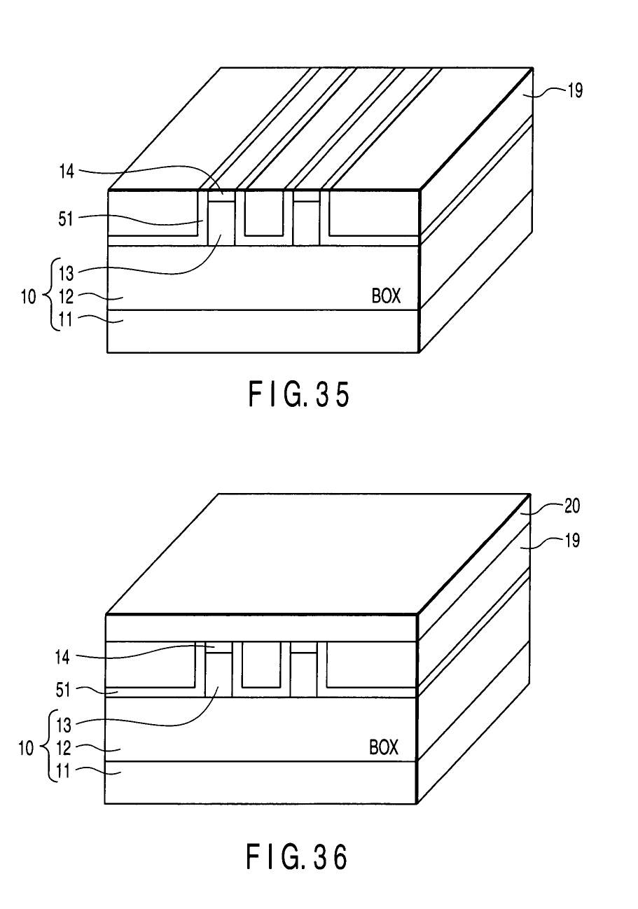

As shown in FIG. 35, after the first polysilicon layer 19 is planarized by, e.g., chemical mechanical polishing (CMP), the first polysilicon layer 19 and insulating film 51 are etched back until the hard masks 14 are exposed.

Subsequently, as shown in FIG. 36, a second polysilicon layer 20 about 50 nm thick is deposited on the first polysilicon layer 19 and hard masks 14. Note that the first and second polysilicon layers 19 and 20 are used as the materials of a gate electrode G.

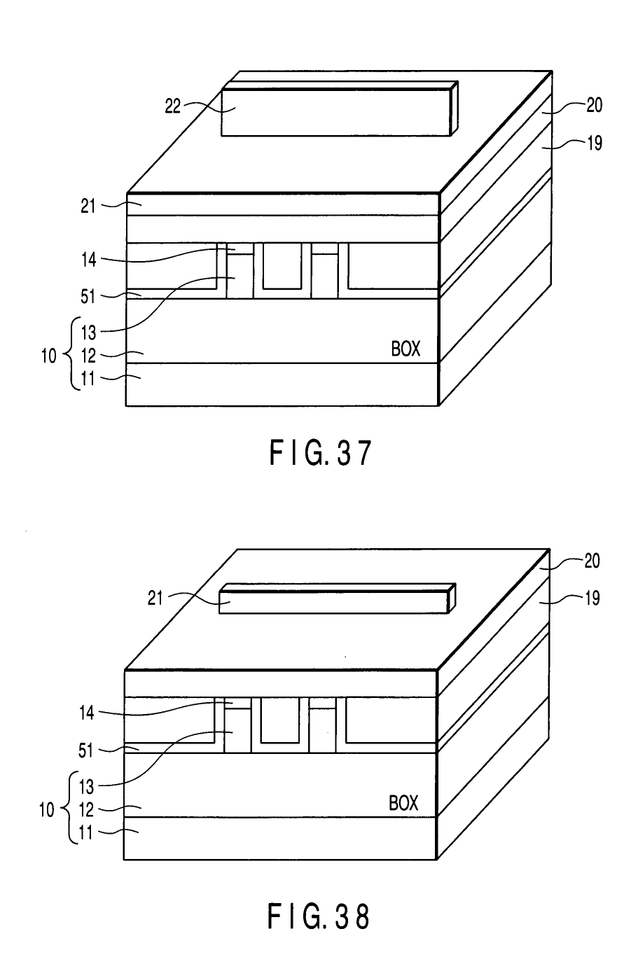

As shown in FIG. 37, a hard mask 21 about 100 nm thick made of an SiN film is deposited on the second polysilicon layer 20, and a resist 22 is formed on the hard mask 21. The resist 22 is then processed into a gate pattern by RIE.

As shown in FIG. 38, the resist 22 is used to process the hard mask 21 into the gate pattern by RIE. After that, the resist 22 is removed.

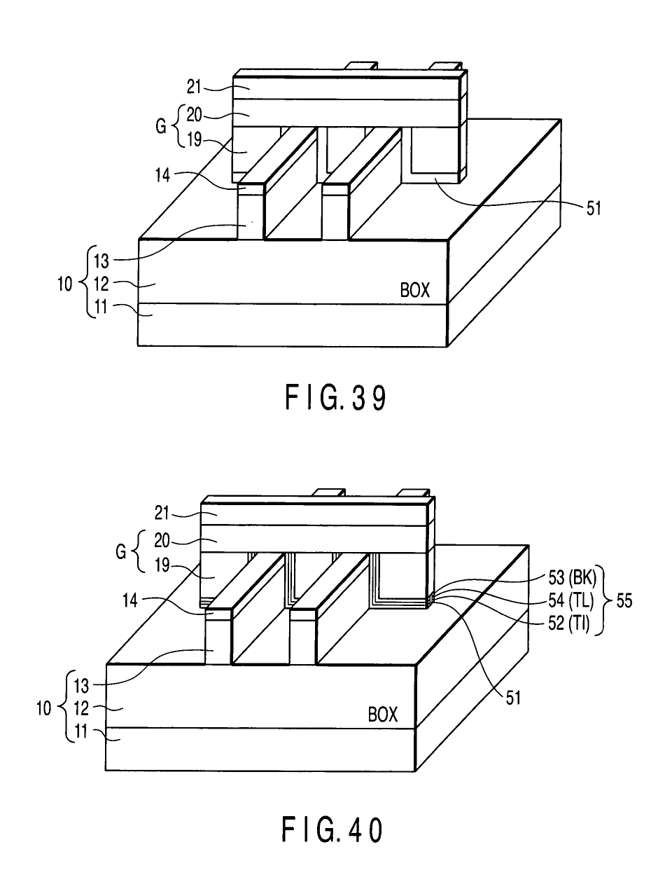

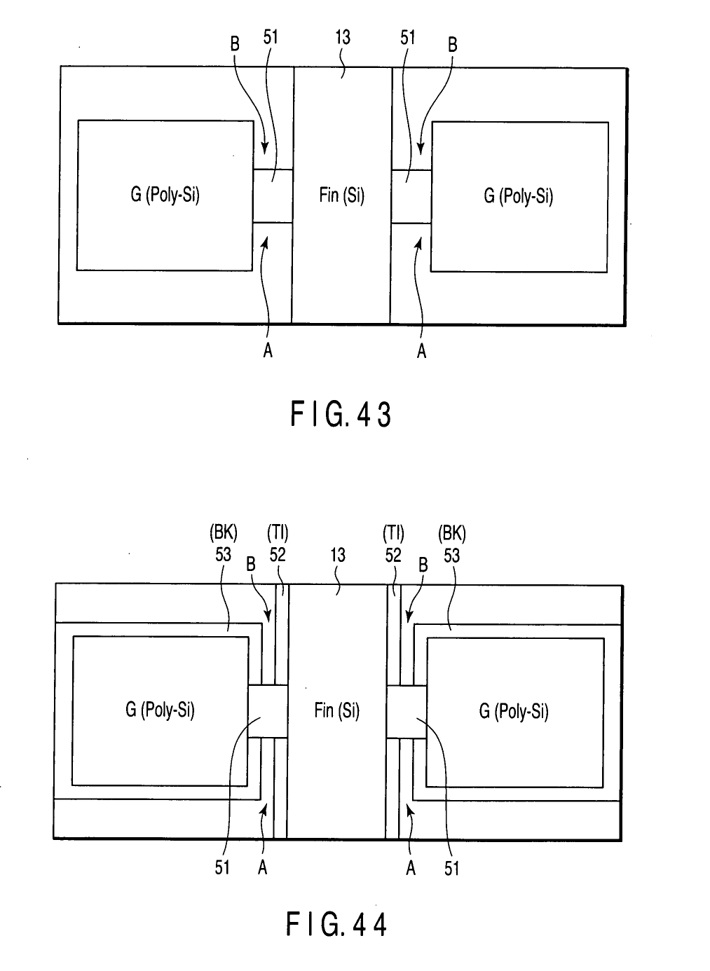

As shown in FIG. 39, the hard mask 21 is used to process the first and second polysilicon layers 19 and 20 and the insulating film 51 by RIE. As a consequence, a gate electrode G is formed across the fin-shaped SOI layers 13. The insulating films 51 exist between the gate electrode G and SOI layer 13 (FIG. 42). After that, the insulating films 51 are removed by about 40 nm from the right and left by isotropic etching such as HF etching. This positions the side surfaces of the insulating films 51 inside the side surfaces of the gate electrode G, forming cavities A and B on the two sides of the insulating films 51 (FIG. 43).

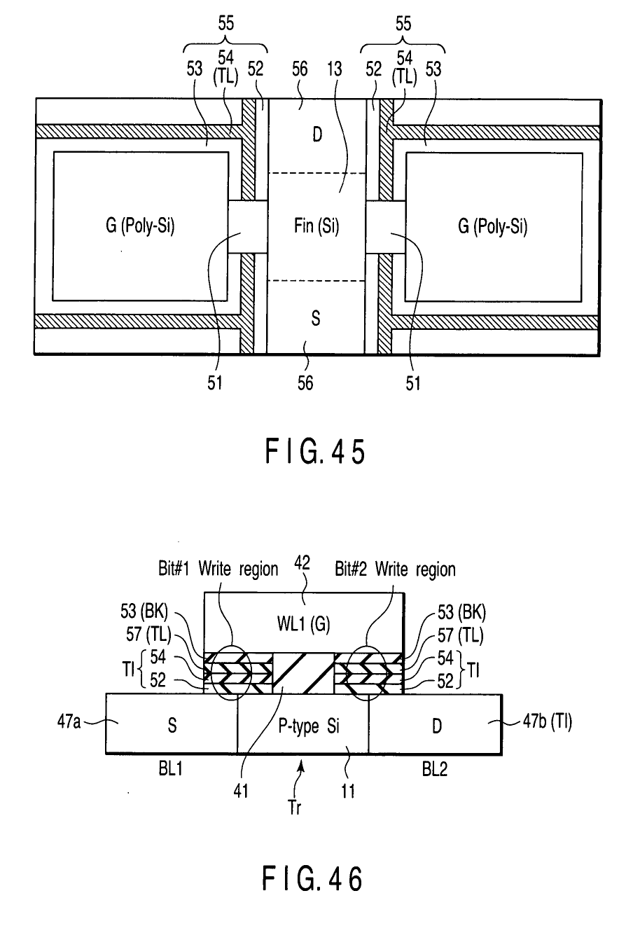

As shown in FIG. 40, ONO films 55 are deposited. The ONO films 55 are formed, e.g., as follows. First, the surface of the gate electrode G and the side surfaces of the SOI layers 13 are simultaneously oxidized in an N₂/O₂ ambient by a rapid-thermal-process. This process forms 3-nm-thick oxide films (SiO₂ films) 52 on the side surfaces of the SOI layers 13, and 3-nm-thick oxide films (SiO₂ films) 53 on the side surfaces of the gate electrode G (FIG. 44). In the cavities A and B, therefore, tunnel gate insulating films TI made of the oxide films 52 and block layers BK made of the oxide films 53 are respectively formed on the opposing surfaces of the SOI layer 13 and gate electrode G (FIG. 44). Then, SiN films (e.g., Si₃N₄ films) 54 (trap layers TL) about 5 nm thick are deposited by LPCVD so as to fill the portions between the oxide films 52 and 53 (FIG. 45).

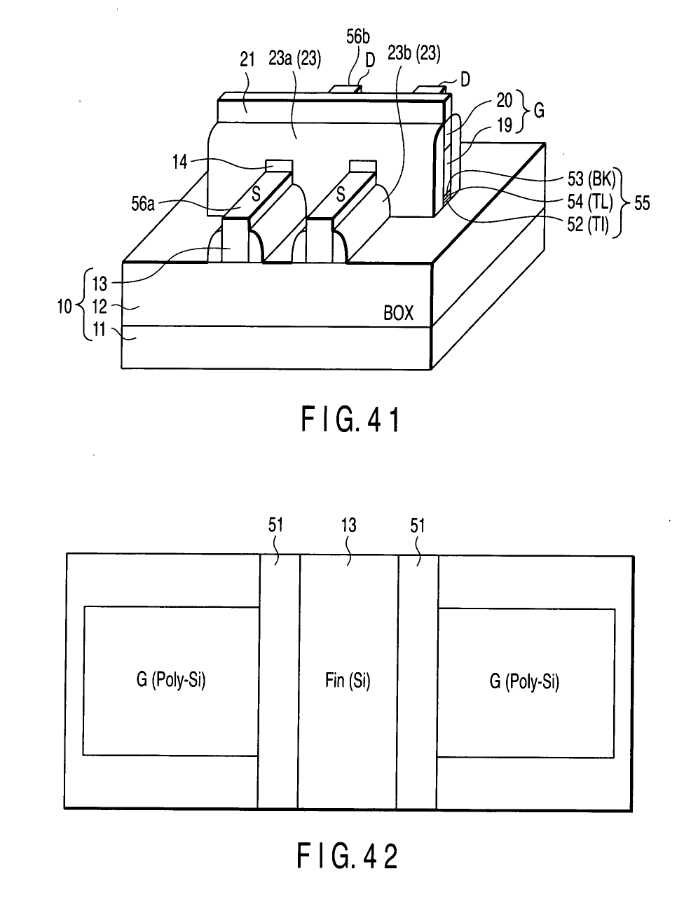

As shown in FIG. 41, a sidewall material 23 made of, e.g., SiO₂ using TEOS is deposited on the hard masks 14 and 21 and the buried insulating film 12, and etched back. This forms gate sidewall layers 23a about 40 nm thick on the side surfaces of the gate electrode G, and fin sidewall layers 23b about 40 nm thick on the side surfaces of the SOI layers 13. After that, the hard masks 14 made of an SiN film on the SOI layers 13 are etched away by SiN-RIE. However, the hard mask 21 made of an SiN film is left behind on the gate electrode G by adjusting the etching conditions. Subsequently, source/drain diffusion layers 56a and 56b are formed in the SOI layers 13 by ion implantation. Manufacturing steps after that are similar to the conventional LSI manufacturing steps. That is, an interlayer film is deposited, contact holes are formed, and an upper interconnection layer is formed.

As described above, the multi-storage EEPROM of Embodiment 2-2 of the present invention can achieve the same effects as in Embodiment 2-1. In addition, the Fin-MOSFET structure can further increase the degrees of micropatterning and integration.

### [2-3] Embodiment 2-3

Embodiment 2-3 is a planar MOSFET in which trap layers TL made of high-k films exist near the source and drain of one transistor, and a layer having a conduction band bottom level higher than that of the two trap layers TL is formed between them.

FIG. 46 is a sectional view of the semiconductor memory device according to Embodiment 2-3 of the present invention. The semiconductor memory device according to Embodiment 2-3 of the present invention will be explained below.

As shown in FIG. 46, Embodiment 2-3 differs from Embodiment 2-1 in that high-k films 57 are used as the trap layers TL. Examples of the high-k film 57 are an HfO₂ film, ZrO₂ film, and TiO₂ film.

Note that this embodiment exhibits the structure obtained by adding the high-k films 57 to the structure of Embodiment 2-1, but it is also possible to eliminate SiN films 54.

As described above, the multi-storage EEPROM of Embodiment 2-3 of the present invention can achieve the same effects as in Embodiment 2-1. In addition, the use of the high-k films 57 as the trap layers TL makes it possible to increase the operating speed and prolong the retention time of the EEPROM.

### [2-4] Embodiment 2-4

Embodiment 2-4 is a Fin-MOSFET in which trap layers TL made of high-k films exist near the source and drain of one transistor, and a layer having a conduction band bottom level higher than that of the two trap layers TL is formed between them.

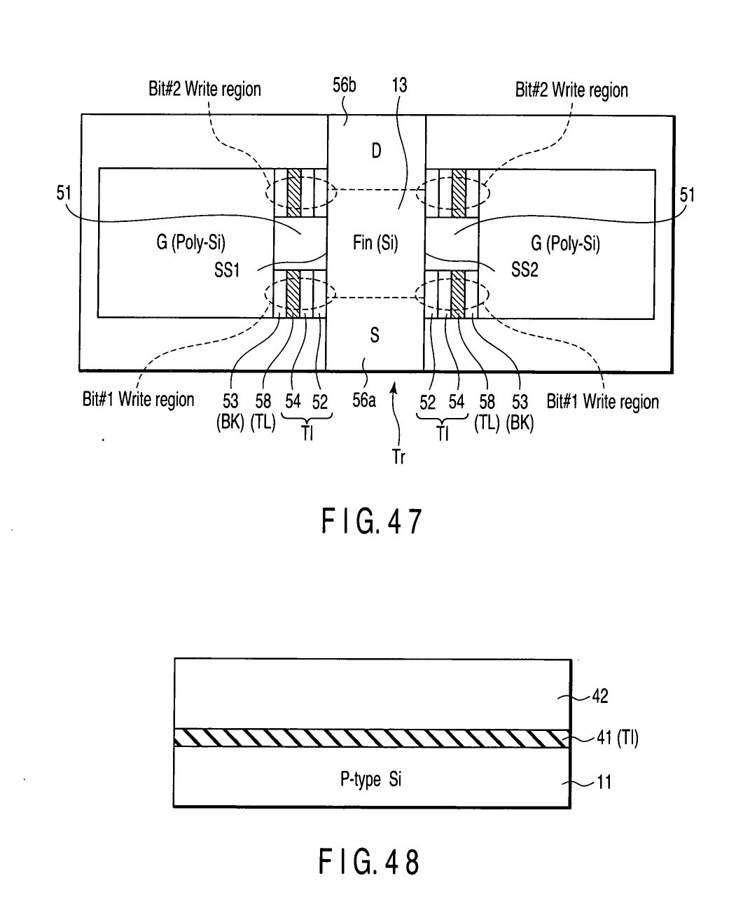

FIG. 47 is a plan view of the semiconductor memory device according to Embodiment 2-4 of the present invention. The semiconductor memory device according to Embodiment 2-4 of the present invention will be explained below.

As shown in FIG. 47, Embodiment 2-4 differs from Embodiment 2-2 in that high-k films 58 are used as the trap layers TL. Examples of the high-k film 58 are an HfO₂ film, ZrO₂ film, and TiO₂ film.

Note that this embodiment exhibits the structure obtained by adding the high-k films 58 to the structure of Embodiment 2-2, but it is also possible to eliminate SiN films 54.

As described above, the multi-storage EEPROM of Embodiment 2-4 of the present invention can achieve the same effects as in Embodiment 2-2. In addition, the use of the high-k films 58 as the trap layers TL makes it possible to increase the operating speed and prolong the retention time of the EEPROM.

### [2-5] Embodiment 2-5

Embodiment 2-5 is a planar MOSFET similar to Embodiment 2-1, but a manufacturing method differs from that of Embodiment 2-1. In Embodiment 2-5, a trap layer TL is deposited in a trench formed by removing a dummy gate, and sidewalls made of a material different from the trap layer TL are formed inside the trench. These sidewalls are used as masks to remove the trap layer TL from the central portion of the trench, a block layer is formed, and a gate electrode is buried in the trench.

FIGS. 48 to 59 are sectional views showing manufacturing steps of the semiconductor memory device according to Embodiment 2-5 of the present invention. A method of manufacturing the semiconductor memory device according to Embodiment 2-5 of the present invention will be explained below.

First, as shown in FIG. 48, an insulating film 41 (tunnel gate insulating film TI) made of an SiO₂ film about 3 nm thick is formed by oxidizing a semiconductor substrate (e.g., an Si substrate) 11. A polysilicon layer 42 about 100 nm thick is deposited on the insulating film 41.

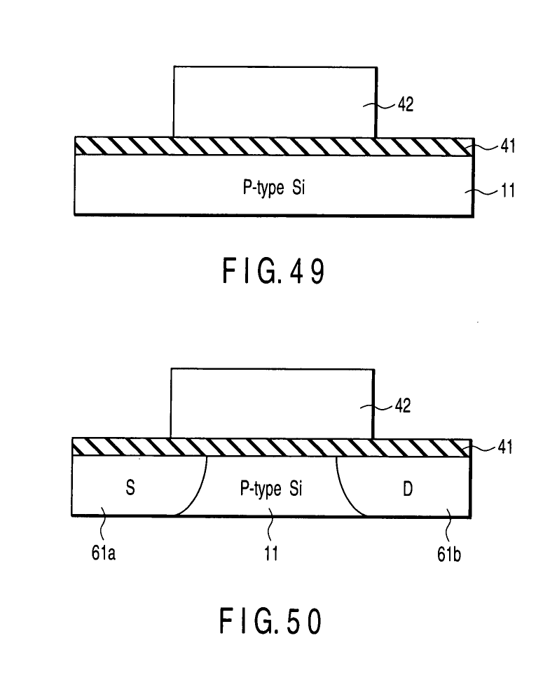

Then, as shown in FIG. 49, the polysilicon layer 42 is patterned into a gate shape by lithography and RIE.

As shown in FIG. 50, source/drain diffusion layers 61a and 61b are formed in the semiconductor substrate 11 by ion implantation.

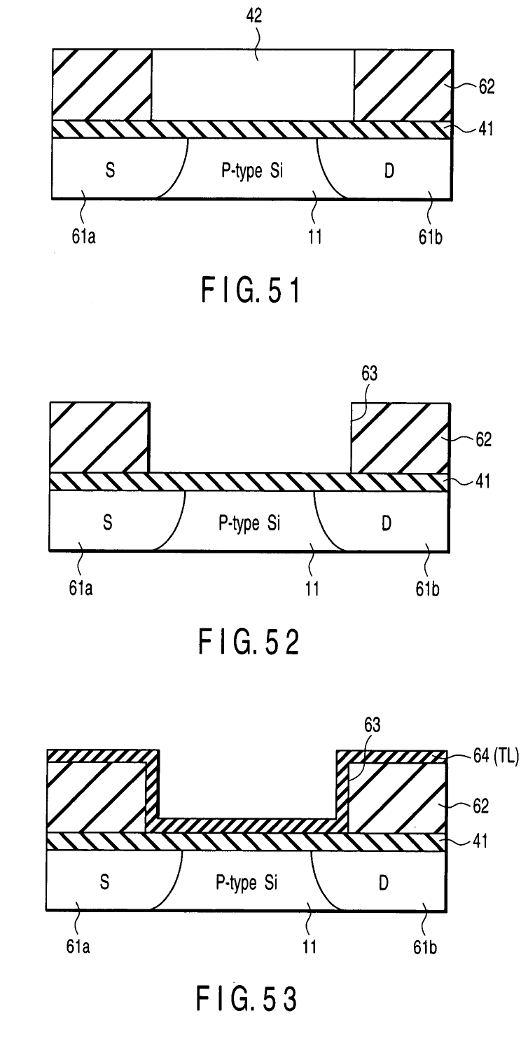

Subsequently, as shown in FIG. 51, an interlayer dielectric film 62 about 200 nm thick made of SiO₂ using TEOS is deposited and planarized by CMP, thereby exposing the upper surface of the polysilicon layer 42.

As shown in FIG. 52, a gate trench 63 for burying a gate is formed by removing the polysilicon layer 42 by, e.g., CDE.

As shown in FIG. 53, the insulating film 41 on the bottom of the gate trench 63 is removed, and a new insulating film 41 is formed. Then, an SiN film (Si₃N₄ film) 64 is deposited as a trap layer TL on the insulating film 41 and interlayer dielectric film 62. The insulating film formation conditions are that, e.g., a 3-nm-thick insulating film 41 is formed in an N₂/O₂ ambient by a rapid-thermal-process, and an SiN film 64 about 5 nm thick is deposited by CVD.

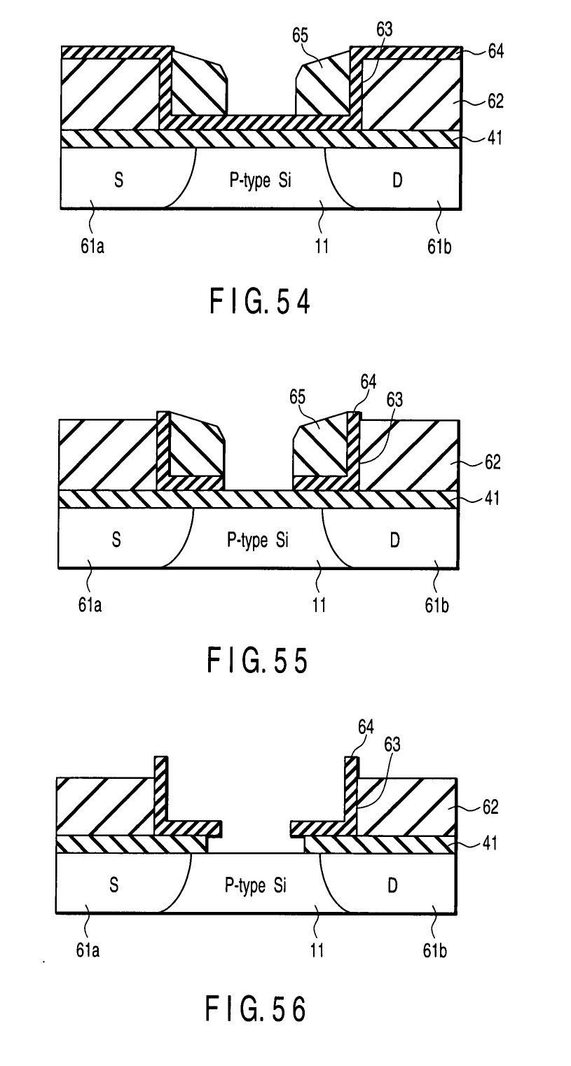

As shown in FIG. 54, sidewall layers 65 about 40 nm thick made of SiO₂ using TEOS or the like are formed on the inner side surfaces of the gate trench 63. The material of the sidewall layers 65 differs from that of the trap layer TL.

As shown in FIG. 55, the sidewall layers 65 are used as masks to etch the SiN film 64 by, e.g., hot phosphoric acid. This exposes the insulating film 41 near the center of the gate trench 63, and exposes the upper surface of the interlayer dielectric film 62.

As shown in FIG. 56, the sidewall layers 65 are removed by using, e.g., HF. In this step, the insulating film 41 near the center of the gate trench 63 and the upper portion of the interlayer dielectric film 62 are also removed.

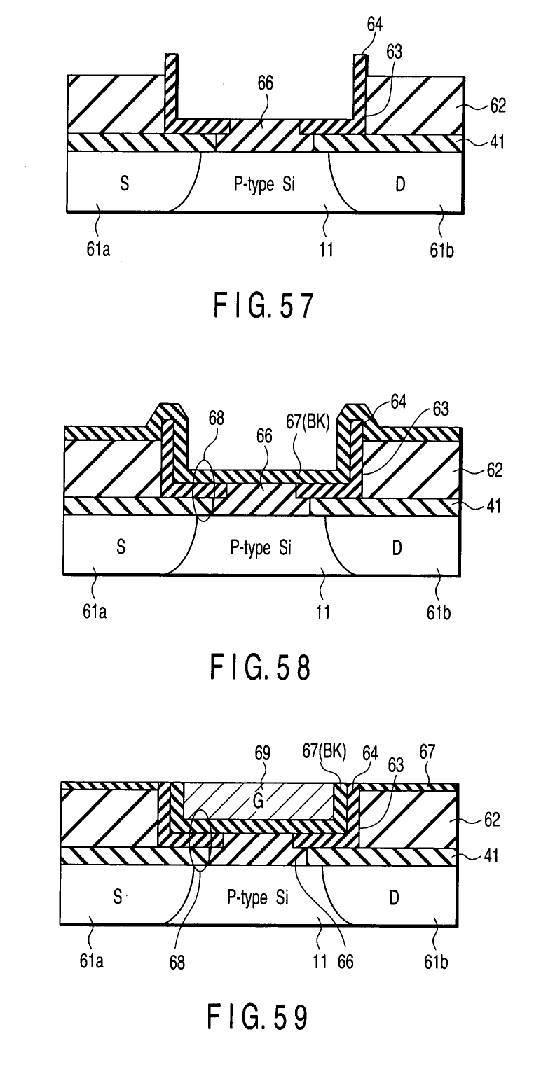

As shown in FIG. 57, an oxide film 66 made of an SiO₂ film or the like is formed by reoxidizing the semiconductor substrate 11 exposed to the bottom of the gate trench 63. The oxide film 66 has a conduction band bottom level higher than that of the material of the trap layer TL made of the SiN film 64.

As shown in FIG. 58, an oxide film 67 (block layer BK, control gate insulating film CI) about 5 nm thick made of, e.g., an SiO₂ film is deposited on the oxide film 66 and interlayer dielectric film 62. In this way, an ONO film 68 is formed.

As shown in FIG. 59, a polysilicon layer 69 about 200 nm thick is deposited, and a gate electrode G is formed only inside the gate trench 63 by planarizing the polysilicon layer 69 (the damascene process). Manufacturing steps after that are similar to the conventional LSI manufacturing steps. That is, an interlayer film is deposited, contact holes are formed, and an upper interconnection layer is formed.

As described above, the multi-storage EEPROM of Embodiment 2-5 of the present invention can achieve the same effects as in Embodiment 2-1.

The manufacturing method of this embodiment can also achieve the effect that a metal gate is readily usable. That is, the gate electrode G can also be formed by using a metal material instead of the polysilicon layer 69. It is also possible to eliminate the block layer BK, depending on the material of the trap layer TL.

### [2-6] Embodiment 2-6

Embodiment 2-6 is a Fin-MOSFET similar to Embodiment 2-2, but a manufacturing method differs from that of Embodiment 2-2. The manufacturing method of Embodiment 2-6 uses sidewalls as in Embodiment 2-5.

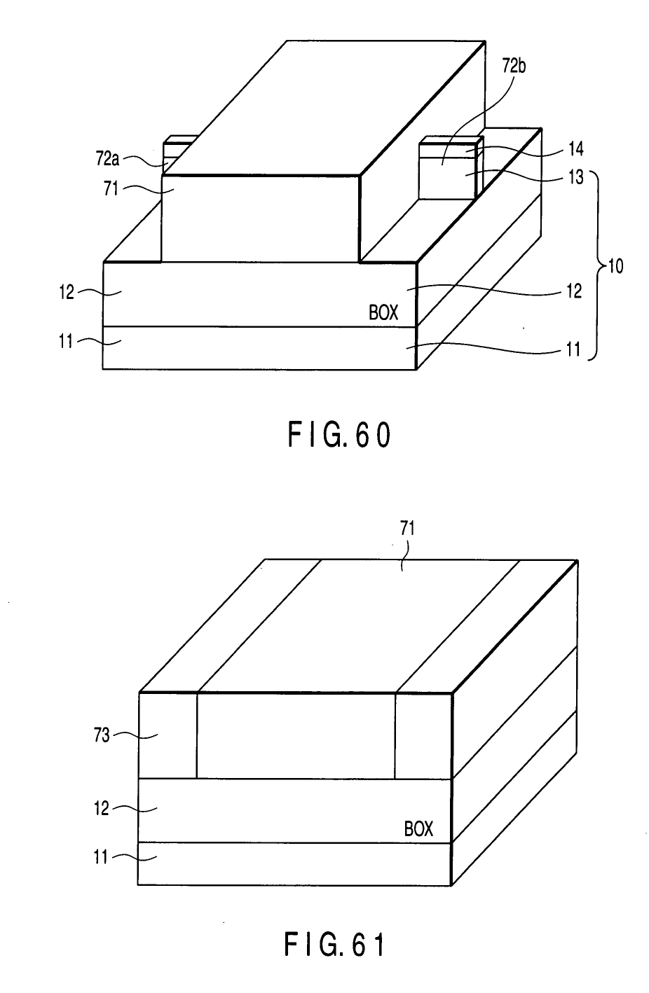

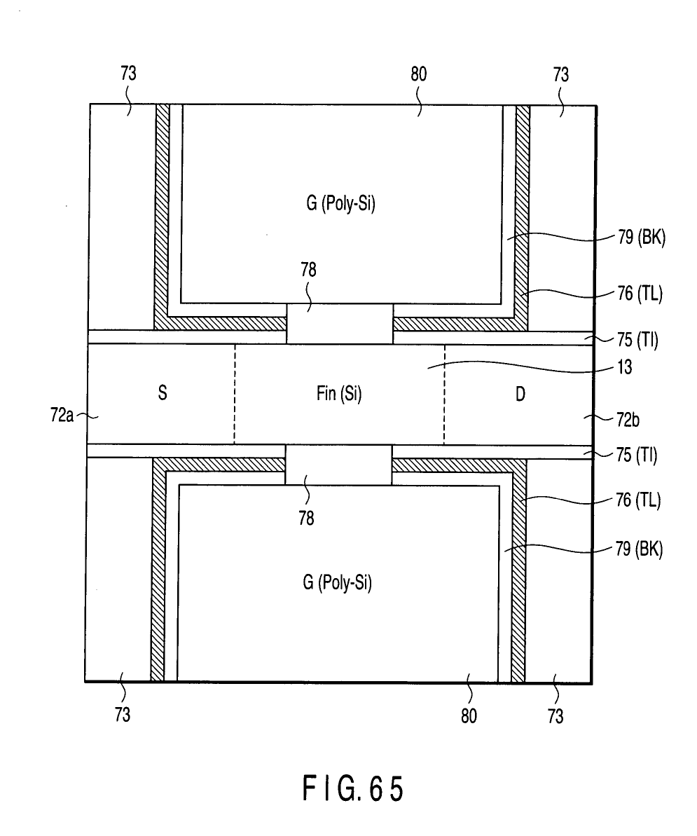

FIGS. 60 to 64 are perspective views showing manufacturing steps of the semiconductor memory device according to Embodiment 2-6 of the present invention. FIG. 65 is a plan view showing a manufacturing step of the semiconductor memory device according to Embodiment 2-6 of the present invention. The method of manufacturing the semiconductor memory device according to Embodiment 2-6 of the present invention will be explained below.

First, as shown in FIG. 60, an SOI substrate 10 having a semiconductor substrate (e.g., an Si substrate) 11, buried insulating film (BOX) 12, and SOI layer 13 is prepared. Doping is then performed on a body region as a prospective channel region of the SOI layer 13. A hard mask 14 is deposited on the SOI layer 13, and patterned into a fin shape. The hard mask 14 is made of, e.g., an SiN film about 70 nm thick. The hard mask 14 is used to process the SOI layer 13 into a fin shape by anisotropic etching such as RIE. Oxide films (not shown) about 3 nm thick are formed by oxidizing the side surfaces of the SOI layer 13, and a polysilicon layer 71 about 200 nm thick is deposited and planarized. The polysilicon layer 71 is then patterned by lithography and RIE. Subsequently, source/drain diffusion layers 72a and 72b are formed by ion implantation.

Then, as shown in FIG. 61, an interlayer dielectric film (PMD) 73 about 200 nm thick made of SiO₂ using TEOS is deposited and planarized by CMP. This exposes the upper surface of the polysilicon layer 71.

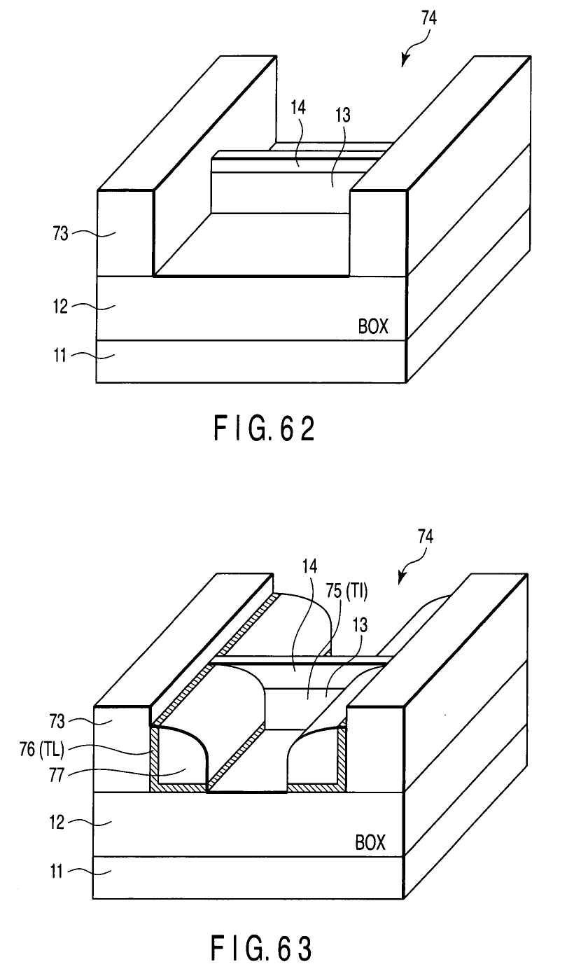

As shown in FIG. 62, a gate trench 74 for burying a gate is formed by removing the polysilicon layer 71 by, e.g., CDE or wet etching.

Subsequently, as shown in FIG. 63, the oxide films (not shown) on the side surfaces of the SOI layer 13 in the gate trench 74 are removed. After that, oxide films 75 (tunnel gate insulating films TI) made of, e.g., SiO₂ films are formed on the side surfaces of the SOI layer 13 (FIG. 65), and SiN films (Si₃N₄ films) 76 are deposited as trap layers TL. The formation conditions of these insulating films are that, e.g., 3-nm-thick oxide films 75 are formed in an N₂/O₂ ambient by a rapid-thermal-process, and SiN films 76 about 5 nm thick are deposited by CVD.

Sidewall layers 77 about 40 nm thick made of SiO₂ using TEOS or the like are formed on the inner side surfaces of the gate trench 74. The material of the sidewall layers 77 differs from that of the trap layers TL. The sidewall layers 77 are used as masks to partially etch the SiN films 76 by, e.g., hot phosphoric acid. More specifically, the SiN films 76 are removed from the side surfaces of the SOI layer 13 near the center of the gate trench 74 in FIG. 63, or near the center of the gate electrode G in FIG. 65 (near the center of the channel, or near the center separated from both the source and drain). Then, the sidewall layers 77 are removed by using HF or the like. This step also partially removes the oxide films 75 from the side surfaces of the SOI layer 13 near the channel center (FIG. 65). After that, an oxide film 78 made of an SiO₂ film or the like is formed by reoxidizing the SOI layer 13 exposed in the gate trench 74 (FIG. 65). The oxide film 78 has a conduction band bottom level higher than that of the material of the trap layers TL made of the SiN films 76.

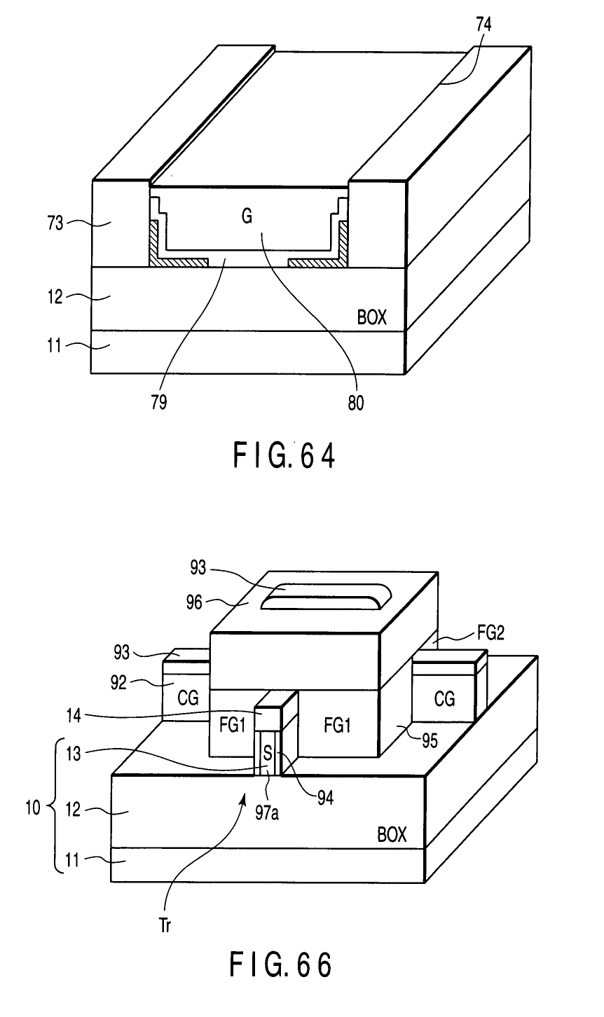

Then, as shown in FIG. 64, an oxide film 79 (block layer BK, control gate insulating film CI) about 5 nm thick is deposited. A polysilicon layer 80 about 200 nm thick is deposited on the oxide film 79, and a gate electrode G is formed only inside the gate trench 74 by planarizing the polysilicon layer 80 (the damascene process). Manufacturing steps after that are similar to the conventional LSI manufacturing steps. That is, an interlayer film is deposited, contact holes are formed, and an upper interconnection layer is formed.

As described above, the multi-storage EEPROM of Embodiment 2-6 of the present invention can achieve the same effects as in Embodiment 2-2.

The manufacturing method of this embodiment can also achieve the effect that a metal gate is readily usable. That is, the gate electrode G can also be formed by using a metal material instead of the polysilicon layer 80. It is also possible to eliminate the block layer BK, depending on the material of the trap layers TL.

A circuit diagram and planar layout pattern diagram of memory cells according to Embodiments 2-1 to 2-6 of the second example described above are the same as those explained in Embodiment 1-4, so an explanation thereof will be omitted.

### [3] Third Example

Each semiconductor memory device according to the third example of the present invention is a multi-storage EEPROM in which a floating MOSFET has a fin structure.

### [3-1] Embodiment 3-1

Embodiment 3-1 is a Fin-MOSFET having four conductive floating gate electrodes in contact with the side surfaces of both a fin and control gate electrode via insulating films, at the intersection of the fin and control gate electrode.

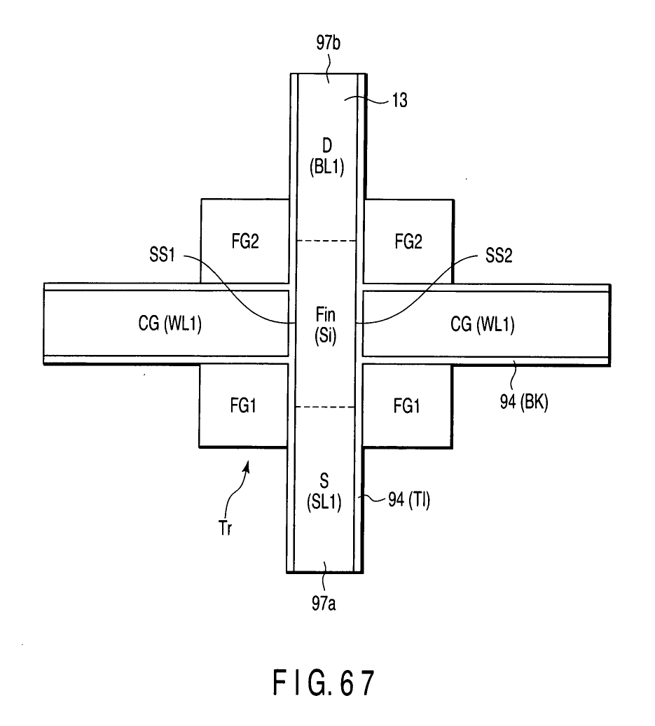

FIG. 66 is a perspective view of the semiconductor memory device according to Embodiment 3-1 of the present invention. FIG. 67 is a plan view of the semiconductor memory device according to Embodiment 3-1 of the present invention. The semiconductor memory device according to Embodiment 3-1 of the present invention will be explained below.

As shown in FIGS. 66 and 67, this embodiment uses an SOI substrate 10. The SOI substrate 10 has a semiconductor substrate (e.g., an Si substrate) 11, a buried insulating film (BOX) 12 formed on the semiconductor substrate 11, and an SOI layer (semiconductor layer) 13 formed on the buried insulating film 12.

The SOI layer 13 has a fin shape. That is, the SOI layer 13 has side surfaces SS1 and SS2 opposing each other. A control gate electrode CG is formed across the side surfaces SS1 and SS2 of the SOI layer 13. Accordingly, the fin-shaped SOI layer 13 and control gate electrode CG intersect each other.

The SOI layer 13 below the control gate electrode CG is a channel region, and a hard mask 14 exists between the control gate electrode CG and channel region. Source/drain diffusion layers 97a and 97b are formed in the SOI layer 13 so as to sandwich the channel region. Accordingly, p-n junctions are formed between the channel region and the source/drain diffusion layers 97a and 97b.

Conductive floating gate electrodes FG1 and FG2 are formed at the four corners of the intersection of the SOI layer 13 and control gate electrode CG. That is, two floating gate electrodes FG1 are formed apart from each on the side surfaces SS1 and SS2 of the SOI layer 13 on the side of the source diffusion layer 97a, and in contact with the SOI layer 13 and control gate electrode CG on the side of the source diffusion layer 97a via insulating films 94. Two floating gate electrodes FG2 are formed apart from each on the side surfaces SS1 and SS2 of the SOI layer 13 on the side of the drain diffusion layer 97b, and in contact with the SOI layer 13 and control gate electrode CG on the side of the drain diffusion layer 97b via insulating films 94.

The insulating films 94 formed on the side surfaces SS1 and SS2 of the SOI layer 13 function as tunnel gate insulating films TI. The insulating films 94 formed on the side surfaces of the control gate electrode CG function as block layers BK.

In the semiconductor memory device as described above, one transistor Tr stores two bits. That is, the floating gate electrodes FG1 on the side of the source diffusion layer 97a form a 1-bit write region, and the floating gate electrodes FG2 on the side of the drain diffusion layer 97b form a 1-bit write region. In this manner, one transistor Tr secures write regions for a total of two bits.

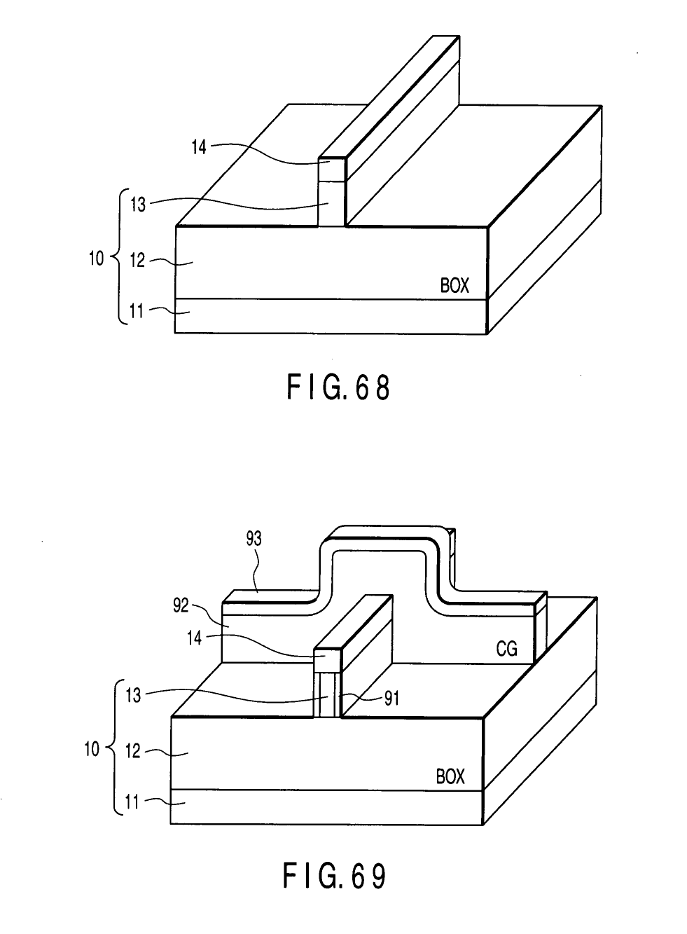

FIGS. 68 to 71 are perspective views showing manufacturing steps of the semiconductor memory device according to Embodiment 3-1 of the present invention. A method of manufacturing the semiconductor memory device according to Embodiment 3-1 of the present invention will be explained below.

First, as shown in FIG. 68, an SOI substrate 10 having a semiconductor substrate (e.g., an Si substrate) 11, buried insulating film (BOX) 12, and SOI layer 13 about 50 nm thick is prepared. Doping is then performed on a body region as a prospective channel region of the SOI layer 13. In this doping, the dose is adjusted so that the channel concentration is about 1E17 cm⁻³. A hard mask 14 is deposited on the SOI layer 13, and patterned into a fin shape. The hard mask 14 is made of, e.g., an SiN film about 70 nm thick. The hard mask 14 is used to process the SOI layer 13 into a fin shape by anisotropic etching such as RIE.

Then, as shown in FIG. 69, oxynitride films 91 about 7.5 nm thick are formed on the side surfaces of the SOI layer 13. A polysilicon layer 92 about 150 nm thick for forming a control gate is deposited on the buried insulating film 12 and the hard mask 14. Since the polysilicon layer 92 is deposited on the fin-shaped SOI layer 13, a large step is formed on the surface of the polysilicon layer 92. Subsequently, an SiN film 93 about 50 nm thick is deposited on the polysilicon layer 92, and processed into a gate pattern. After that, the SiN film 93 is used as a mask to process the polysilicon layer 92 by RIE, thereby forming a control gate electrode CG.

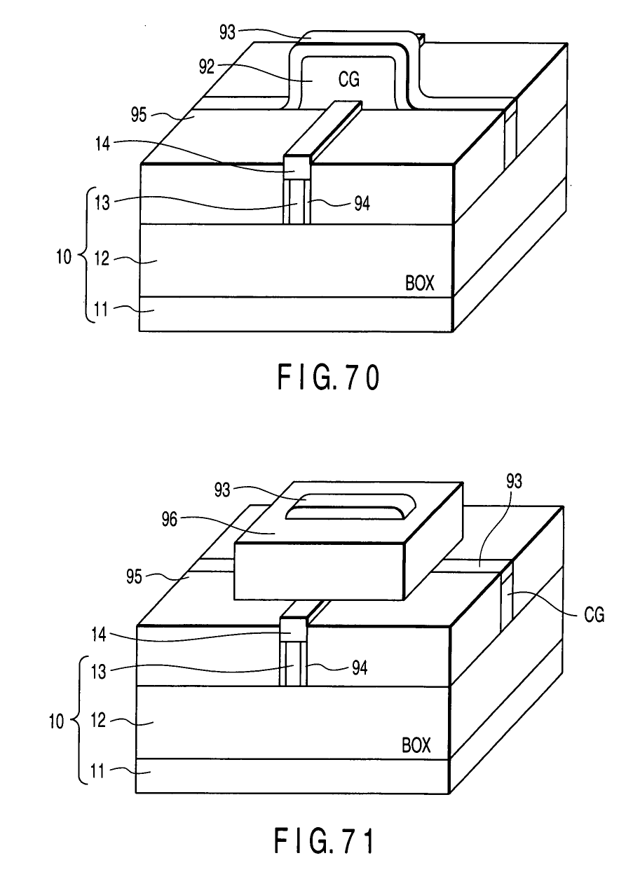

As shown in FIG. 70, after the oxynitride films 91 on the side surfaces of the SOI layer 13 are removed by HF or the like, insulating films 94 about 7.5 nm thick made of oxynitride films or the like are formed on the side surfaces of the SOI layer 13 and the side surfaces of the control gate electrode CG again. A polysilicon layer 95 about 300 nm thick for forming floating gate electrodes is deposited on the entire surface, and planarized by CMP. The polysilicon layer 95 is then etched back by anisotropic etching such as RIE until the SiN film 14 on the SOI layer 13 is exposed. Consequently, the control gate electrode CG protrudes in the form of a projection at the intersection of the fin-shaped SOI layer 13 and control gate electrode CG.

As shown in FIG. 71, a sidewall layer 96 about 20 nm thick made of SiO₂ using TEOS is formed on the side surfaces of the projection of the control gate electrode CG.

Subsequently, as shown in FIGS. 66 and 67, the projection of the control gate electrode CG and the sidewall layer 96 are used as masks to process the polysilicon layer 95 by RIE, thereby forming floating gate electrodes FG1 and FG2. After that, ion implantation for forming a source and drain and activation annealing (RTA at 900° C. to 1,000° C.) are performed to form source/drain diffusion layers 97a and 97b in the SOI layer 13. Manufacturing steps after that are similar to the conventional LSI manufacturing steps. That is, an interlayer film is deposited, contact holes are formed, and an upper interconnection layer is formed. Note that the sidewall layer 96 may be either removed or left behind before, e.g., the interlayer film is deposited.

As described above, the multi-storage EEPROM of Embodiment 3-1 of the present invention uses a fin structure. At the intersection of the fin-shaped SOI layer 13 and control gate electrode CG, the four conductive floating gate electrodes FG1 and FG2 are formed in contact with the side surfaces of both the SOI layer 13 and control gate electrode CG via the insulating films 94. The use of this double-gate-structure Fin-MOSFET makes it possible to increase the degree of micropatterning, increase the density, and reduce the cost of the multi-storage EEPROM.

Also, in the manufacturing method of the present invention, the polysilicon layer 95 for forming floating gates is buried in the spaces between the fin-shaped SOI layer 13 and control gate electrode CG (i.e., in the regions except for the SOI layer 13 and control gate electrode CG), the sidewall layer 96 is formed on the side surfaces of the control gate electrode CG protruding in the form of a projection at the intersection of the SOI layer 13 and control gate electrode CG, and the projection-shaped gate protruding portion and sidewall layer 96 are used as masks to process the floating gate electrodes FG1 and FG2 by RIE. Therefore, the four floating gate electrodes FG1 and FG2 can be formed in self-alignment at the intersection of the fin-shaped SOI layer 13 and control gate electrode CG. This makes it possible to simplify the process by omitting a lithography step requiring severe alignment accuracy, and further increase the degree of micropatterning and decrease the density of the EEPROM.

### [3-2] Embodiment 3-2

Embodiment 3-2 is a Fin-MOSFET having two conductive floating gate electrodes in contact with the side surfaces of both a fin and control gate electrode via insulating films, at the intersection of the fin and control gate electrode.

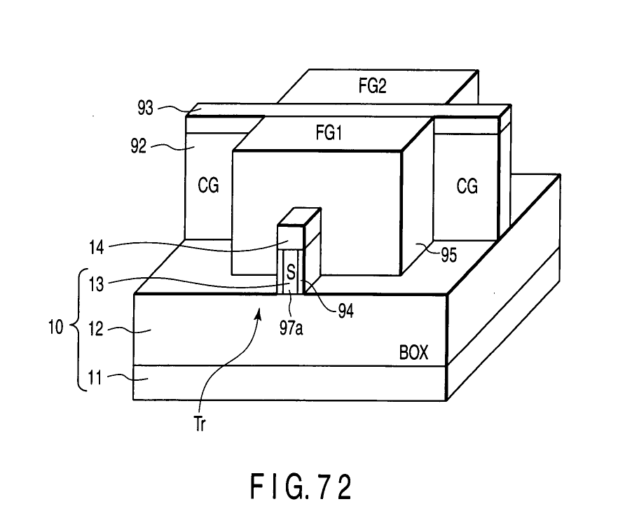

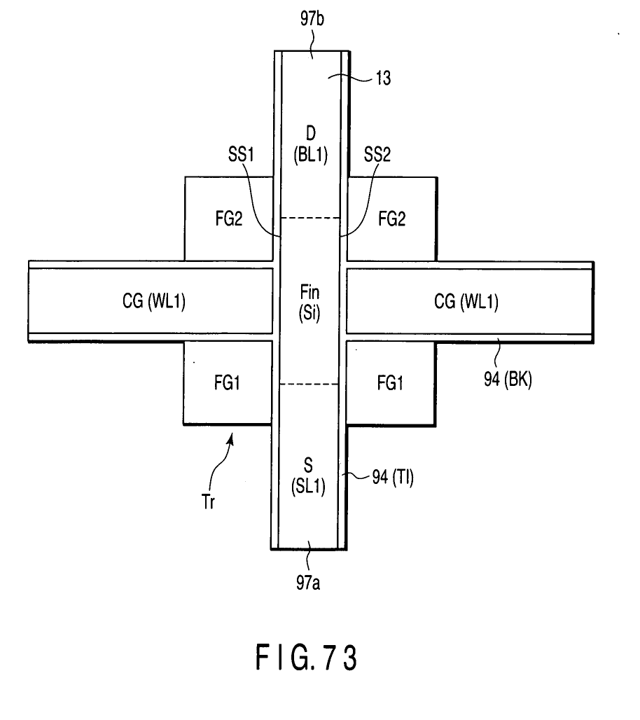

FIG. 72 is a perspective view of the semiconductor memory device according to Embodiment 3-2 of the present invention. FIG. 73 is a plan view of the semiconductor memory device according to Embodiment 3-2 of the present invention. The semiconductor memory device according to Embodiment 3-2 of the present invention will be explained below.

As shown in FIGS. 72 and 73, Embodiment 3-2 differs from Embodiment 3-1 in the shapes of a control gate electrode CG and floating gate electrodes FG1 and FG2. Details are as follows.

In Embodiment 3-1, the upper surface of the control gate electrode CG has a projection. In Embodiment 3-2, the upper surface of the control gate electrode CG is flat.

In Embodiment 3-1, the two floating gate electrodes FG1 are separated by the SOI layer 13 on the side of the source diffusion layer 97a, and the two floating gate electrodes FG2 are separated by the SOI layer 13 on the side of the drain diffusion layer 97b. In Embodiment 3-2, the floating gate electrode FG1 continues across an SOI layer 13 on the side of a source diffusion layer 97a, and the floating gate electrode FG2 continues across the SOI layer 13 on the side of a drain diffusion layer 97b.

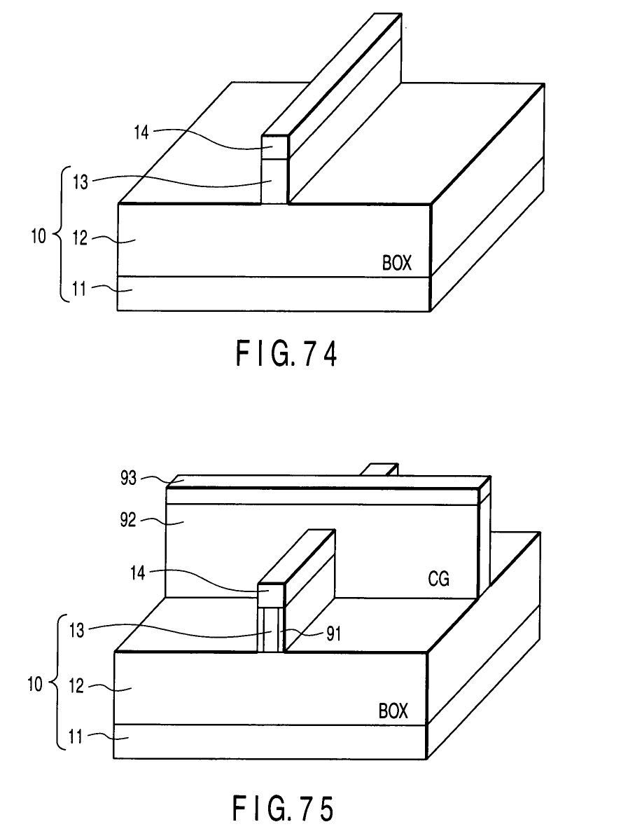

FIGS. 74 to 77 are perspective views showing manufacturing steps of the semiconductor memory device according to Embodiment 3-2 of the present invention. A method of manufacturing the semiconductor memory device according to Embodiment 3-2 of the present invention will be explained below.

First, as shown in FIG. 74, an SOI substrate 10 having a semiconductor substrate 11, buried insulating film (BOX) 12, and SOI layer 13 about 50 nm thick is prepared. Doping is then performed on a body region as a prospective channel region of the SOI layer 13. In this doping, the dose is adjusted so that the channel concentration is about 1E17 cm⁻³. A hard mask 14 is deposited on the SOI layer 13, and patterned into a fin shape. The hard mask 14 is made of, e.g., an SiN film about 70 nm thick. The hard mask 14 is used to process the SOI layer 13 into a fin shape by anisotropic etching such as RIE.

Then, as shown in FIG. 75, oxynitride films 91 about 7.5 nm thick are formed on the side surfaces of the SOI layer 13. A polysilicon layer 92 about 300 nm thick for forming a control gate is deposited on the buried insulating film 12 and the hard mask 14, and planarized by CMP. Subsequently, an SiN film 93 about 50 nm thick is deposited on the polysilicon layer 92, and processed into a gate pattern. After that, the SiN film 93 is used as a mask to process the polysilicon layer 92 by RIE, thereby forming a control gate electrode CG.

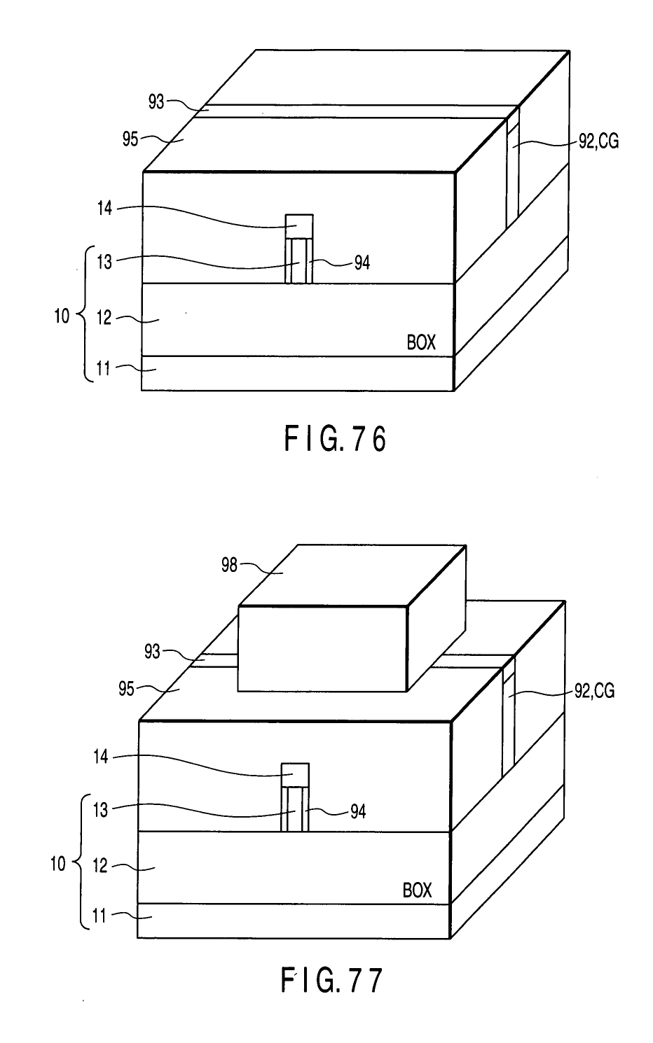

As shown in FIG. 76, after the oxynitride films 91 on the side surfaces of the SOI layer 13 are removed by HF or the like, insulating films 94 about 7.5 nm thick made of oxynitride films or the like are formed on the side surfaces of the SOI layer 13 and the side surfaces of the control gate electrode CG again. A polysilicon layer 95 about 400 nm thick for forming floating gate electrodes is deposited on the entire surface, and planarized by CMP. The polysilicon layer 95 is then etched back by anisotropic etching such as RIE until the SiN film 93 is exposed.

As shown in FIG. 77, a resist 98 is formed on the SiN film 93 and polysilicon layer 95 at the intersection of the control gate electrode CG and SOI layer 13. The resist 98 is then processed by lithography.

Subsequently, as shown in FIGS. 72 and 73, the resist 98 is used as a mask to process the polysilicon layer 95 by RIE, thereby forming floating gate electrodes FG1 and FG2. After that, the resist 98 is removed. Then, ion implantation for forming a source and drain and activation annealing (RTA at 900° C. to 1,000° C.) are performed to form source/drain diffusion layers 97a and 97b in the SOI layer 13. Manufacturing steps after that are similar to the conventional LSI manufacturing steps. That is, an interlayer film is deposited, contact holes are formed, and an upper interconnection layer is formed.

As described above, the multi-storage EEPROM of Embodiment 3-2 of the present invention can achieve the same effects as in Embodiment 3-1.

In addition, while Embodiment 3-1 uses the four floating gate electrodes FG1 and FG2, Embodiment 3-2 uses the two floating gate electrodes FG1 and FG2. That is, the fin does not separate each of the floating gate electrodes FG1 and FG2. This structure effectively facilitates lithography of the floating gate electrodes FG1 and FG2 because the device surface is flat.

### [3-3] Embodiment 3-3

Embodiment 3-3 will explain a circuit diagram and planar layout pattern diagram of memory cells according to Embodiments 3-1 and 3-2.

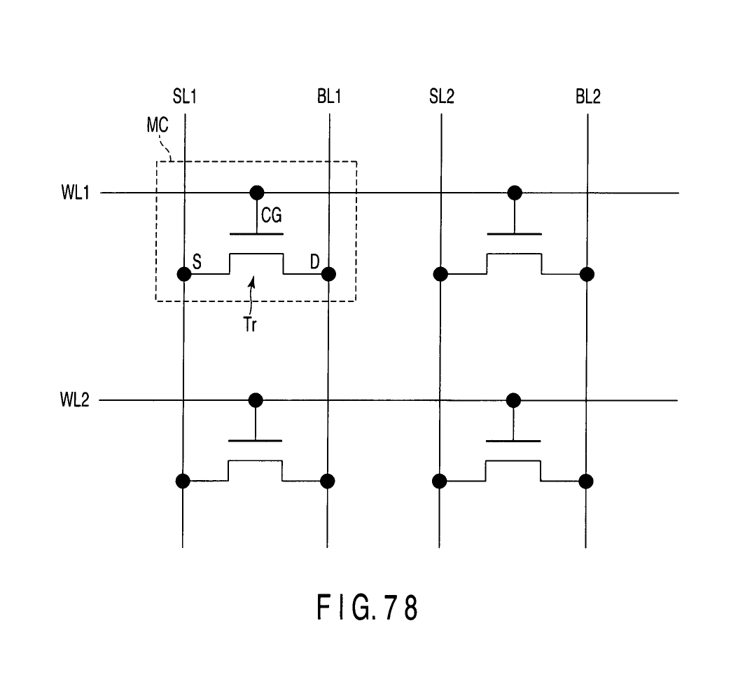

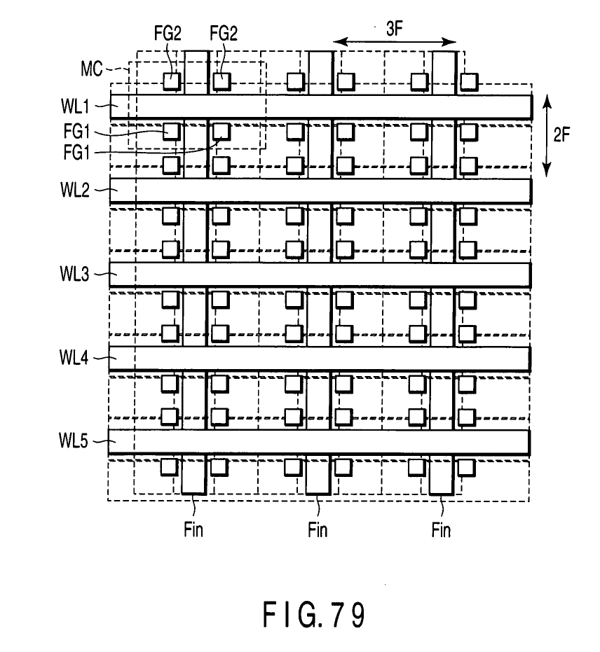

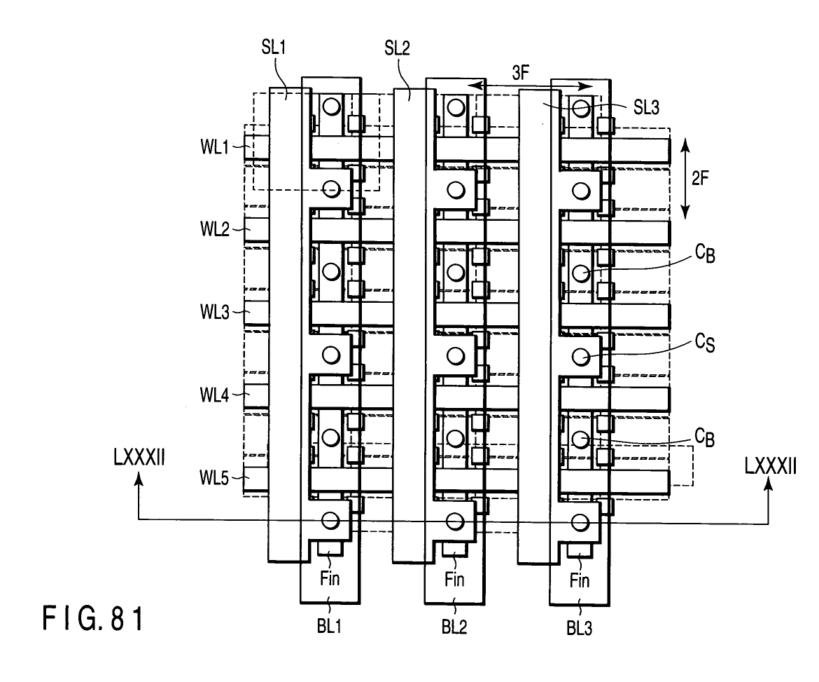

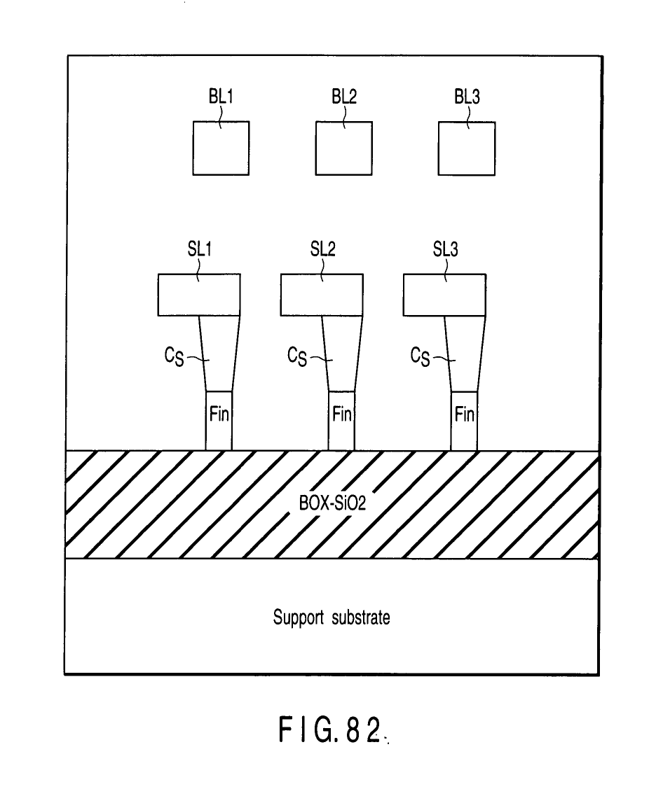

FIG. 78 is a circuit diagram of memory cells of a semiconductor memory device according to Embodiment 3-3 of the present invention. FIGS. 79 to 81 are planar layout pattern diagrams of the memory cells of the semiconductor memory device according to Embodiment 3-3 of the present invention. FIG. 82 is a sectional view of the memory cell of the semiconductor memory device taken along a line LXXXII-LXXXII in FIG. 81. The semiconductor memory device according to Embodiment 3-3 of the present invention will be explained below. Note that these diagrams correspond to, e.g., the plan view of FIG. 67 in Embodiment 3-1, and the plan view of FIG. 73 in Embodiment 3-2.

As shown in FIG. 78, a plurality of fin transistors Tr as explained in Embodiments 3-1 and 3-2 are arranged and connected to word lines WL, bit lines BL, and source lines SL, thereby forming a circuit. In one memory cell MC, the transistor Tr has a control gate CG (control gate electrode CG) connected to a word line WL1, a source S (source diffusion layer 97a) connected to a source line SL1, and a drain D (drain diffusion layer 97b) connected to a bit line BL1. One transistor Tr forms a 2-bit multi-storage memory cell (that performs a device operation similar to an EEPROM).

As shown in FIG. 79, the word lines WL (control gate electrodes CG) and fins Fin (SOI layers 13) intersect each other, and floating gate electrodes FG1 and FG2 are formed at the four corners of each intersection.

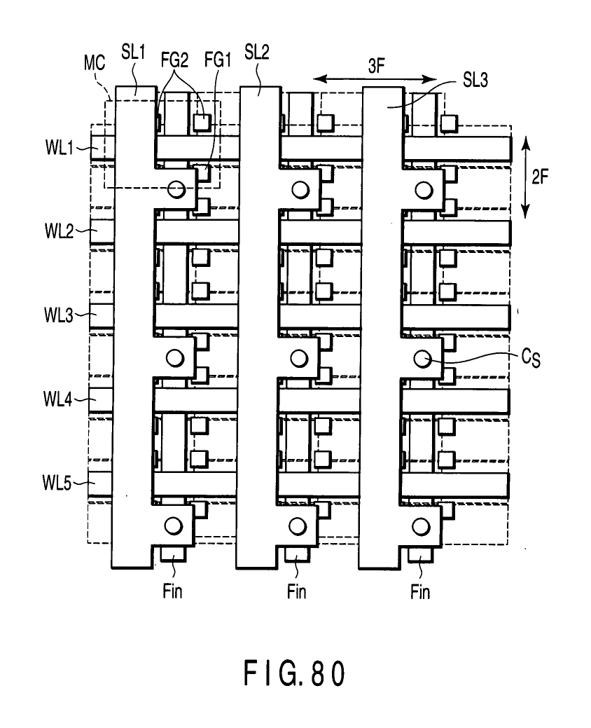

As shown in FIG. 80, source lines SL running in the same direction as the fins Fin are formed in an upper layer of the fins Fin. A portion of each source line SL is extended to a position above the fin Fin, and connected to the fin Fin (source) by a source line contact CS (FIG. 82).

As shown in FIG. 81, the bit lines BL running in the same direction as the source lines SL are formed in an upper layer of the source lines SL (FIG. 82). Each bit line BL is placed above the fin Fin, and connected to the fin Fin (drain) by a bit line contact CB.

This planar layout pattern makes it possible to, e.g., arrange the word lines WL at a 2F pitch (F: the half of a minimum pith of lithography), and arrange the fins Fin at a 3F pitch. As a consequence, a 6F₂-NOR cell array using a Fin-FET can be formed.

The present invention is not limited to the above embodiments, and can be variously modified as follows when practiced without departing from the spirit and scope of the invention.

(1) The example using the SOI substrate 10 in each embodiment can also use an ordinary bulk substrate.

(2) The first example as an example of a Fin-MOSFET is also applicable to a planar MOSFET.

(3) The metal source/drain regions in the first example contain a metal or metal silicide.

(4) Although the second example uses the p-n junction type source/drain diffusion layers, it is also possible to use Schottky junction type source/drain regions as in the first example. Since the high-temperature annealing process can be omitted in this case, the device is particularly effective in Embodiment 2-3 or 2-4 using the low-heat-resistance, high-k film.

(5) In the second example, the insulating layer having a conduction band bottom level higher than that of the two trap layers TL in one transistor Tr is formed between the two trap layers TL. However, this insulating layer need only separate the trap layers TL; it is not always necessary to physically separate the tunnel gate insulating films TI and block layers BK above and below the trap layers TL.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a semiconductor substrate;
an insulating film formed on the semiconductor substrate;
a fin-shaped semiconductor layer formed on the insulating film, and having a first side surface and second side surface opposing each other;
a gate electrode formed across the first side surface and second side surface of the semiconductor layer;
a trap layer formed between the gate electrode and the first side surface of the semiconductor layer;
a tunnel gate insulating film formed between the trap layer and the first and second side surfaces of the semiconductor layer;
a block layer formed between the trap layer and the gate electrode;
a channel region formed in the semiconductor layer below the gate electrode; and
a source region and drain region formed in the semiconductor layer to sandwich the channel region and containing a metal, a Schottky junction being formed between the channel region and each of the source region and the drain region.

2. The device according to claim 1, wherein the trap layer is made of one of a nitride film and a high-k film.

3. The device according to claim 1, wherein the gate electrode is made of one of a polysilicon layer and a metal layer.

4. The device according to claim 1, wherein the tunnel gate insulating film, the trap layer, and the block layer form an oxide-nitride-oxide (ONO) film.

5. The device according to claim 1, wherein the trap layer on a side of the source region forms a first 1-bit write region, and the trap layer on a side of the drain region forms a second 1-bit write region.

6. The device according to claim 1, which further comprises an interlayer dielectric film formed around the gate electrode, and
in which the gate electrode is made of a metal layer, and
an upper surface of the gate electrode is leveled with an upper surface of the interlayer dielectric film.

7. A semiconductor memory device comprising:
a semiconductor layer;
a channel region formed in the semiconductor layer;
a source region and drain region formed in the semiconductor layer to sandwich the channel region;
a gate electrode opposing the channel region;
a first trap layer formed between the gate electrode and the source region;
a first tunnel gate insulating film formed between the first trap layer and the source region;
a first block layer formed between the first trap layer and the gate electrode;
a second trap layer formed between the gate electrode and the drain region;
a second tunnel gate insulating film formed between the second trap layer and the drain region;
a second block layer formed between the second trap layer and the gate electrode; and
a first insulating film formed between the first trap layer and the second trap layer, and made of a material having a conduction band bottom level higher than a conduction band bottom level of the first trap layer and the second trap layer.

8. The device according to claim 7, wherein each of the first trap layer and the second trap layer is made of one of a nitride film or a high-k film.

9. The device according to claim 7, wherein the first insulating film is made of a silicon oxide film.

10. The device according to claim 7, wherein
the first tunnel gate insulating film, the first trap layer, and the first block layer form an ONO film, and
the second tunnel gate insulating film, the second trap layer, and the second block layer form an ONO film.

11. The device according to claim 7, wherein
the first trap layer forms a first 1-bit write region, the second trap layer forms a second 1-bit write region, and
the first insulating film insulates the first write region and the second write region.

12. The device according to claim 7, which further comprises:
a semiconductor substrate; and
a second insulating film formed on the semiconductor substrate, and
in which the semiconductor layer is formed on the second insulating film, and has a fin shape with a first side surface and second side surface opposing each other, and
the gate electrode is placed on a side of the first side surface of the semiconductor layer.

13. A semiconductor memory device manufacturing method comprising:
forming a first insulating film on a semiconductor layer;
forming a gate electrode material on the first insulating film;
removing the first insulating film to position side surfaces of the first insulating film inside side surfaces of the gate electrode material to form a first cavity and a second cavity on two sides of the first insulating film;
forming a first tunnel gate insulating film and a first block layer on opposing surfaces of the semiconductor layer and the gate electrode material, respectively, in the first cavity, and a second tunnel gate insulating film and a second block layer on opposing surfaces of the semiconductor layer and the gate electrode material, respectively, in the second cavity; and
forming a first trap layer between the first tunnel gate insulating film and the first block layer, and a second trap layer between the second tunnel gate insulating film and the second block layer,
wherein a material of the first insulating film has a conduction band bottom level higher than a conduction band bottom level of a material of the first trap layer and the second trap layer.

14. The method according to claim 13, wherein the first cavity and the second cavity are formed by removing the first insulating film by isotropic etching.

15. The method according to claim 13, wherein each of the first trap layer and the second trap layer is made of one of a nitride film and a high-k film.

16. The method according to claim 13, wherein the first insulating film is made of a silicon oxide film.

17. The method according to claim 13, wherein
the first tunnel gate insulating film, the first trap layer, and the first block layer form an ONO film, and
the second tunnel gate insulating film, the second trap layer, and the second block layer form an ONO film.

18. The method according to claim 13, further comprising:
forming a second insulating film on the semiconductor layer; and
forming the semiconductor layer having a fin shape with a first side surface and second side surface opposing each other on the second insulating film.

19. A semiconductor memory device manufacturing method comprising:
forming a tunnel gate insulating film on a semiconductor layer;
forming an interlayer dielectric film having a trench on the tunnel gate insulating film;
forming a trap layer in the trench;
forming a sidewall layer on side surfaces of the trench on the trap layer;
removing the trap layer from a bottom of the trench exposed from the sidewall layer to expose a portion of the tunnel gate insulating film;
removing the sidewall layer and the exposed portion of the tunnel gate insulating film to expose a portion of the semiconductor layer;
forming, on the exposed portion of the semiconductor layer, an insulating film made of a material having a conduction band bottom level higher than a conduction band bottom level of a material of the trap layer;
forming a block layer on the trap layer and the insulating film; and
forming a gate electrode in the trench on the block layer.

20. The method according to claim 19, wherein the sidewall layer and the trap layer are made of different materials.
